(19) United States
(12) Patent Application Publication
(10) Pub. No.: US 2026/0096187 A1
(43) Pub. Date: Apr. 2, 2026

(54) JUNCTION DIODE ISOLATION

(71) Applicant: TEXAS INSTRUMENTS INCORPORATED, Dallas, TX (US)

(72) Inventors: Dong Seup Lee, Allen, TX (US); Sunglyong Kim, Allen, TX (US); Doug Weiser, Plano, TX (US)

(21) Appl. No.: 18/902,578

(22) Filed: Sep. 30, 2024

(51) Int. Cl. H01L 29/78; H01L 29/06; H01L 29/66

(52) U.S. Cl. CPC H10D 84/154; H10D 30/0281; H10D 62/127

(57) ABSTRACT

The present disclosure generally relates to junction diode isolation in an integrated circuit die. In an example, a semiconductor device includes a diode and a transistor. The diode is in a semiconductor substrate. The diode includes an anode region, an n-type well, a cathode region, and an n-type buried layer each in the semiconductor substrate. The cathode region is in the n-type well. The n-type buried layer extends from the n-type well laterally towards the anode region. The transistor includes a source region and a drain region in the semiconductor substrate. The source and drain regions are between the anode and cathode regions. A lateral distance is between the cathode region and a lateral edge of the n-type buried layer proximate the anode region. The lateral distance is parallel to a channel length of the transistor. The lateral distance decreases from proximate the transistor to distal from the transistor.

### BACKGROUND

Substrate parasitic leakage and voltage are challenges when devices are integrated into or on a same integrated circuit (IC) die. Various techniques have been developed to address such leakage and voltage. However, challenges may still persist, particularly for certain applications, such as high voltage applications.

### SUMMARY

An example described herein is a semiconductor device. The semiconductor device includes a diode and a transistor. The diode is in a semiconductor substrate. The diode includes an anode region, an n-type well, a cathode region, and an n-type buried layer. The anode region is in the semiconductor substrate. The n-type well is in the semiconductor substrate. The cathode region is in the semiconductor substrate and in the n-type well. The n-type buried layer is in the semiconductor substrate. The n-type buried layer extends from the n-type well laterally towards the anode region. The transistor includes a source region and a drain region in the semiconductor substrate. The source region and the drain region are between the anode region and the cathode region. A lateral distance is between the cathode region and a lateral edge of the n-type buried layer proximate the anode region. The lateral distance is parallel to a channel length of the transistor. The lateral distance decreases from proximate the transistor to distal from the transistor.

Another example is a is a semiconductor device. The semiconductor device includes a diode and a transistor. The diode is in a semiconductor substrate. The diode includes an anode region and a cathode region. The anode region is in the semiconductor substrate and at an upper surface of the semiconductor substrate. The cathode region is in the semiconductor substrate and at the upper surface of the semiconductor substrate. The transistor includes a source region and a drain region in the semiconductor substrate and at the upper surface of the semiconductor substrate. The source region and the drain region is between the anode region and the cathode region. The anode region extends laterally parallel to a channel width of the transistor proximate to the transistor and extends laterally non-parallel to the channel width distally away from the transistor. A first lateral distance between the anode region and the cathode region decreases as the anode region extends laterally non-parallel to the channel width.

A further example is a method. A diode is formed in a semiconductor substrate. The diode includes an anode region, an n-type well, a cathode region, and an n-type buried layer. The anode region is in the semiconductor substrate. The n-type well is in the semiconductor substrate. The cathode region is in the semiconductor substrate and in the n-type well. The n-type buried layer is in the semiconductor substrate. The n-type buried layer extends from the n-type well laterally towards the anode region. A transistor is formed and includes a source region and a drain region in the semiconductor substrate. The source region and the drain region are between the anode region and the cathode region. A lateral distance is between the cathode region and a lateral edge of the n-type buried layer proximate the anode region. The lateral distance is parallel to a channel length of the transistor. The lateral distance decreases from proximate the transistor to distal from the transistor.

The foregoing summary outlines rather broadly various features of examples of the present disclosure in order that the following detailed description may be better understood. Various features and advantages of such examples will be described hereinafter. The described examples may be readily utilized as a basis for modifying or designing other examples that are within the scope of the appended claims.

### BRIEF DESCRIPTION OF THE DRAWINGS

So that the manner in which the above recited features can be understood in detail, reference is made to the following detailed description taken in conjunction with the accompanying drawings.

FIG. 1 is a layout of a portion of an integrated circuit (IC) die according to some examples.

FIG. 2 is a layout of an inset as an example of the inset of FIG. 1 according to some examples.

FIG. 3 is a cross-sectional view of a cross-section of FIG. 2 according to some examples.

FIG. 4 is a cross-sectional view of another cross-section of FIG. 2 according to some examples.

FIGS. 5A, 5B, 6A, 6B, 7A, 7B, 8A, 8B, 9A, 9B, 10A, 10B, 11A, and 11B are cross-sectional views of the IC die of FIGS. 1, 2, 3, and 4 at various stages of manufacturing according to an example method.

FIG. 12 is a layout of an inset as an example of the inset of FIG. 1 according to some examples.

FIG. 13 is a cross-sectional view of a cross-section of FIG. 12 according to some examples.

FIG. 14 is a layout of an inset as an example of the inset of FIG. 1 according to some examples.

FIG. 15 is a cross-sectional view of a cross-section of FIG. 14 according to some examples.

FIG. 16 is a cross-sectional view of another cross-section of FIG. 14 according to some examples.

FIG. 17 is a layout of an inset as an example of the inset of FIG. 1 according to some examples.

FIG. 18 is a cross-sectional view of a cross-section of FIG. 17 according to some examples.

FIGS. 19, 20, 21, and 22 are respective layouts of an inset as an example of the inset of FIG. 1 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. Other examples may include any permutation of including or excluding aspects or features that are described. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates generally, but not exclusively, to junction diode isolation in an integrated circuit (IC) die. Some examples include a semiconductor device that includes a diode and a transistor. In some examples, the diode includes an anode region, a diode n-type well, a cathode region, and a diode n-type buried layer in a semiconductor substrate. The cathode region is in the diode n-type well, and the diode n-type buried layer extends from the diode n-type well towards the anode region. The transistor includes a source region and a drain region in the semiconductor substrate and between the anode region and the cathode region. In some examples, a lateral distance between the cathode region and a lateral edge of the first n-type buried layer proximate the anode region decreases from proximate the transistor to distal from the transistor. In some examples, the anode region extends laterally parallel to a channel width of the transistor proximate to the transistor. The anode region further extends laterally non-parallel and non-perpendicular to the channel width and a channel length of the transistor distally away from the transistor, where a lateral distance between the anode region and the cathode region decreases as the anode region extends laterally non-parallel and non-perpendicular to the channel width and the channel length. Other examples, such as where the diode includes a diode p-type well and a diode p-type buried layer, are also described.

According to some examples, a breakdown voltage of the diode may be reduced such that voltage clamping when an electrostatic discharge (ESD) event occurs may be more likely to be performed by the diode and not the transistor. The diode may be more robust for such voltage clamping because the diode may have a larger area in which current may flow to discharge the ESD event. Also, an area used by the diode on the IC die may be reduced such that area of the IC die may be used more efficiently. Further, an electric field may be relatively smooth in the semiconductor substrate of the IC die between the transistor and the diode. Other benefits and advantages may be achieved.

Various examples are described subsequently. Although the specific examples may illustrate various aspects of the above generally described features, examples may incorporate any combination of the above generally described features (which are described in more detail in examples below).

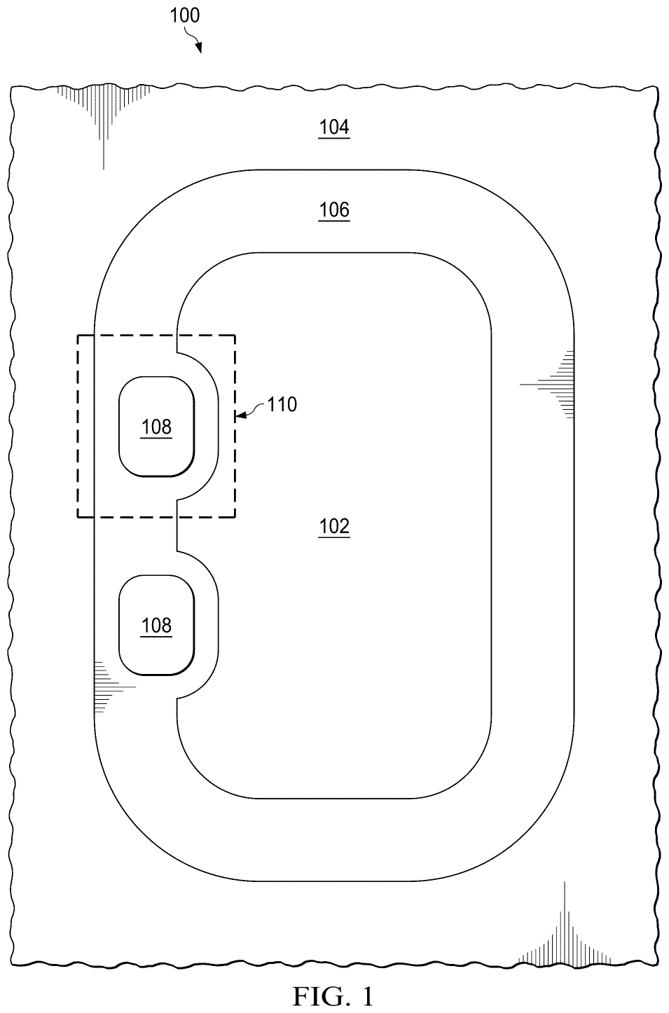

FIG. 1 is a layout of a portion of an integrated circuit (IC) die 100 according to some examples. The IC die 100 includes a high voltage device area 102 and a low voltage device area 104. The IC die 100 includes a junction diode area 106 between the high voltage device area 102 and the low voltage device area 104. The junction diode area 106 is colloquially a “racetrack” configuration and laterally encircles the high voltage device area 102. Level-shift transistor areas 108 are in the junction diode area 106.

One or more devices, such as transistors, diodes, etc., may be in the high voltage device area 102, which devices may operate at and/or have an operating voltage rating for a relatively high voltage. One or more devices, such as transistors, diodes, etc., may be in the low voltage device area 104, which devices may operate at and/or have an operating voltage rating for a relatively low voltage less than the high voltage of device(s) in the high voltage device area 102. In some examples, device(s) in an area interior to the junction diode area 106 may operate at a voltage different than (e.g., less than or greater than) a voltage at which device(s) in an area exterior to the junction diode area 106 operate.

The junction diode area 106 includes a diode that includes a cathode region and an anode region, as detailed subsequently. The cathode region is in the junction diode area 106 and laterally encircles the high voltage device area 102 within the junction diode area 106. The anode region is also in the junction diode area 106 and laterally encircles the cathode region in the junction diode area 106. The diode in the junction diode area 106 may provide a junction isolation between the high voltage device area 102 and the low voltage device area 104.

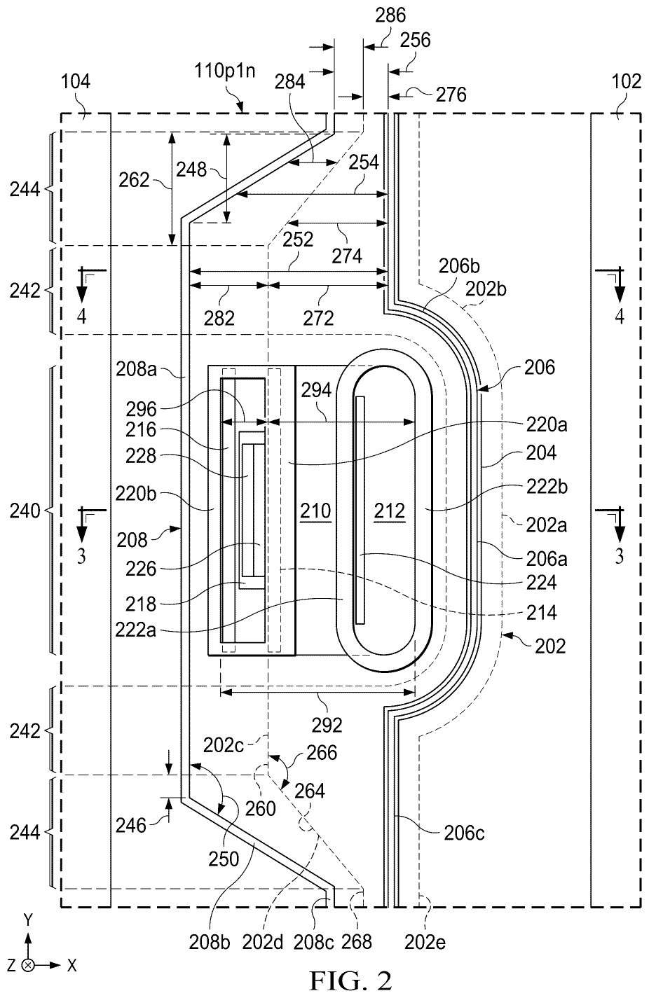

A level-shift transistor area 108 includes a level-shift transistor, which may be or include a laterally diffused metal-oxide-semiconductor (LDMOS) transistor. The level-shift transistor is laterally between the cathode region and the anode region of the diode in the junction diode area 106. The level-shift transistor may be electrically connected between a device in the high voltage device area 102 and a device in the low voltage device area 104. The level-shift transistor may communicate signals or voltages between the device in the high voltage device area 102 and the device in the low voltage device area 104. FIG. 2 shows an inset 110 in the layout of the IC die 100. The inset 110 includes one of the level-shift transistor areas 108 and portions of the junction diode area 106 proximate to that level-shift transistor area 108.

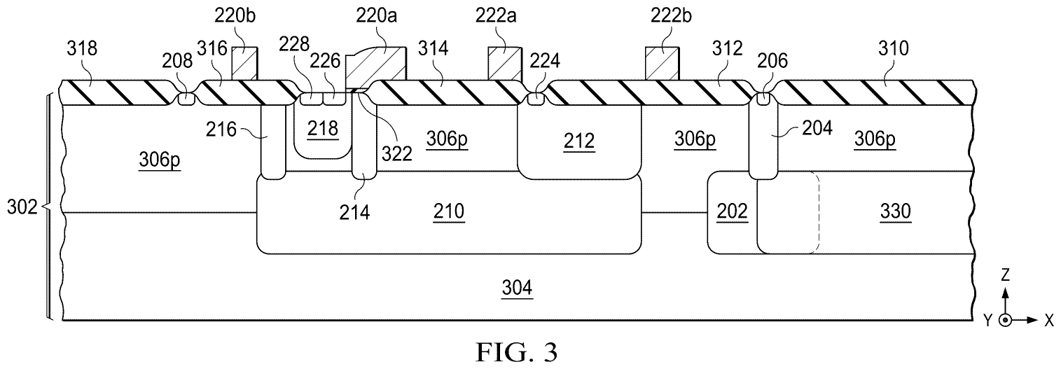

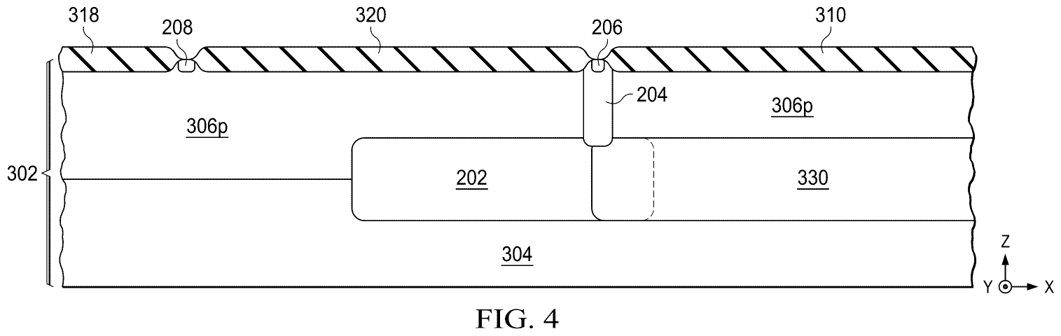

FIG. 2 is a layout of an inset 110p1n as an example of the inset 110 of FIG. 1 according to some examples. FIG. 2 shows a cross-section 3-3 and a cross-section 4-4. FIG. 3 shows a cross-sectional view of the cross-section 3-3 of FIG. 2, and FIG. 4 shows a cross-sectional view of the cross-section 4-4 of FIG. 2. FIGS. 2, 3, and 4 are described together. FIGS. 2, 3, and 4 also show X-Y-Z axes for orienting the figures relative to each other. In FIGS. 2, 3, and 4, the level-shift transistor is an n-type LDMOS transistor in a p-type epitaxial layer (or more generally, semiconductor substrate), as will be detailed subsequently.

The layout of FIG. 2 is in and/or on a semiconductor substrate 302, which is shown in FIGS. 3 and 4. The semiconductor substrate 302, in the illustrated examples, includes a semiconductor support (or handle) substrate 304 (or handle wafer) and an epitaxial layer 306p. The semiconductor support substrate 304 may be a bulk semiconductor substrate, a semiconductor-on-insulator (SOI) substrate, or any other appropriate substrate. The epitaxial layer 306p is epitaxially grown on or over the semiconductor support substrate 304. The epitaxial layer 306p may be or include silicon (Si), silicon germanium (SiGe), gallium arsenide (GaAs), gallium nitride (GaN), the like, or a combination thereof. In some examples, the semiconductor support substrate 304 is or includes a silicon substrate (which may be singulated from a bulk silicon wafer at the conclusion of semiconductor processing), and the epitaxial layer 306p is or includes a layer of silicon. In some examples, the epitaxial layer 306p may be omitted, and a semiconductor material of the semiconductor substrate 302 (e.g., in or on which devices are formed) may be or include silicon (Si), silicon germanium (SiGe), gallium arsenide (GaAs), the like, or a combination thereof. The semiconductor substrate 302 has a top major surface in and/or on which devices (e.g., diodes, transistors, etc.) are generally disposed and formed. In the illustrated example, the semiconductor material of the semiconductor substrate 302 (e.g., the epitaxial layer 306p) is p-doped with a p-type dopant. In the illustrated example, the epitaxial layer 306p is p-doped with a p-type dopant (e.g., boron (B)) with a concentration in a range from 1×10¹⁴ cm⁻³ to 1×10¹⁵ cm⁻³. Other doping concentrations may be implemented.

FIGS. 3 and 4 also show isolation structures 310, 312, 314, 316, 318, 320 (not shown in FIG. 2) at the top major surface of the semiconductor substrate 302. The isolation structures 310-320, as illustrated, are local oxidation of silicon (LOCOS) structures. In other examples, the isolation structures 310-320 may be shallow trench isolations (STIs). The isolation structures 312-316, 320 may be an integral isolation structure (e.g., with various parts thereof referenced by different reference numerals in the figures for convenience). A gate dielectric layer 322 is also at the top major surface of the semiconductor substrate 302 and extends from the isolation structure 314. The gate dielectric layer 322 may be or include silicon oxide, silicon nitride, the like, or a combination thereof.

Referring to FIGS. 2, 3, and 4, an n-type drift layer 202 is disposed in the semiconductor substrate 302 (e.g., the epitaxial layer 306p and semiconductor support substrate 304). The n-type drift layer 202 in the illustrated example is a buried layer. As used herein, a buried layer is a layer in a semiconductor substrate (e.g., the semiconductor substrate 302) and with characteristics, such as conductivity type or dopant concentration, that is spaced apart from a top surface of the semiconductor substrate (e.g., the top major surface of the semiconductor substrate 302) by a spacing layer or material that has a significantly different characteristic, such as different conductivity type or different dopant concentration. For example a buried layer may be an n-doped diffusion layer spaced apart from the top surface of the semiconductor substrate by an n-type or p-type in situ doped epitaxial layer. In the cross-sectional view of FIG. 3, the n-type drift layer 202 extends laterally from under the isolation structure 310 to under the isolation structure 312, and in the cross-sectional view of FIG. 4, the n-type drift layer 202 extends laterally from under the isolation structure 310 to under the isolation structure 320. More details of the n-type drift layer 202 will be described subsequently in the context of the layout of FIG. 2.

An n-type well 204 is disposed in the semiconductor substrate 302 (e.g., the epitaxial layer 306p). The n-type well 204 extends from proximate the top major surface of the semiconductor substrate 302 to and contacting (e.g., extending into) the n-type drift layer 202. The n-type well 204 is laterally between the isolation structure 310 and the isolation structure 312 in the cross-sectional view of FIG. 3 and between the isolation structure 310 and the isolation structure 320 in the cross-sectional view of FIG. 4.

A cathode region 206 is disposed in the semiconductor substrate 302 (e.g., the epitaxial layer 306p). The cathode region 206 is in the n-type well 204 and extends from the top major surface of the semiconductor substrate 302 into the semiconductor substrate 302. The cathode region 206 is laterally between the isolation structure 310 and the isolation structure 312 in the cross-sectional view of FIG. 3 and between the isolation structure 310 and the isolation structure 320 in the cross-sectional view of FIG. 4.

An anode region 208 is disposed in the semiconductor substrate 302 (e.g., the epitaxial layer 306p). The anode region 208 extends from the top major surface of the semiconductor substrate 302 into the semiconductor substrate 302. The anode region 208 is laterally between the isolation structure 316 and the isolation structure 318 in the cross-sectional view of FIG. 3 and between the isolation structure 320 and the isolation structure 318 in the cross-sectional view of FIG. 4.

The n-type drift layer 202, n-type well 204, and cathode region 206 are doped with a same dopant conductivity type (e.g., n-type), and the anode region 208 is doped with an opposite conductivity type (e.g., p-type). The diode in the junction diode area 106 includes the cathode region 206, n-type well 204, n-type drift layer 202, and anode region 208. As will be described, a level-shift transistor (e.g., an LDMOS transistor) is laterally disposed between the cathode region 206 and the anode region 208 of the diode.

In some examples, the n-type drift layer 202 may be an n-type layer doped with an n-type dopant (e.g., phosphorous and/or arsenic) at a concentration in a range from about 1×10¹⁷ cm⁻³ to about 2×10²⁰ cm⁻³. In some examples, the n-type well 204 may be an n-well doped with an n-type dopant at a concentration in a range from about 1×10¹⁷ cm⁻³ to about 2×10²⁰ cm⁻³. In some examples, the cathode region 206 may be n-doped with an n-type dopant at a concentration in a range from about 1×10²⁰ cm⁻³ to about 3×10²¹ cm⁻³, and the anode region 208 may be p-doped with a p-type dopant at a concentration in a range from about 1×10²⁰ cm⁻³ to about 3×10²¹ cm⁻³.

The level-shift transistor is laterally between the cathode region 206 and the anode region 208 in a transistor area 240 shown in FIG. 2, which includes the cross-section 3-3 of FIG. 3. Components of the level-shift transistor have a generally rectangular shape (e.g., including a rectangular shape with two or four rounded corners) in the layout view of FIG. 2.

Referring to FIGS. 2 and 3, an n-type drift layer 210 is disposed in the semiconductor substrate 302 (e.g., the epitaxial layer 306p and semiconductor support substrate 304). The n-type drift layer 210 in the illustrated example is a buried layer. The n-type drift layer 210 is at a depth in the semiconductor substrate 302 that is generally the same depth of the n-type drift layer 202. The n-type drift layer 210 is laterally separated from the n-type drift layer 202. The n-type drift layer 210 extends laterally from under the isolation structure 312 to under the isolation structure 316, including under the isolation structure 314. The n-type drift layer 210, as illustrated in FIG. 2, is generally rectangular with rounded corners proximate the cathode region 206 of the diode.

N-type wells 212, 214, 216 are disposed in the semiconductor substrate 302 (e.g., the epitaxial layer 306p). The n-type wells 212, 214, 216 each extend from proximate the top major surface of the semiconductor substrate 302 to and contacting the n-type drift layer 210. The n-type well 212 extends from under the isolation structure 312 (e.g., from a same lateral location as the n-type drift layer 210) to under the isolation structure 314. The n-type well 214 is under the isolation structure 314 and the gate dielectric layer 322. The n-type wells 212, 214 are laterally separated. The n-type well 216 is under the isolation structure 316. As shown in the layout of FIG. 2, the n-type well 212 is generally rectangular with four rounded corners, and the n-type wells 214, 216 are generally rectangular. Respective widths of the n-type wells 212, 214, 216 are equal to and co-extensive with a width of the n-type drift layer 210, which widths are parallel to a channel width (indicated subsequently) of the level-shift transistor (e.g., in y-directions).

A drain region 224 is disposed in the semiconductor substrate 302 (e.g., the epitaxial layer 306p). The drain region 224 is in the n-type well 212 and extends from the top major surface of the semiconductor substrate 302 into the semiconductor substrate 302. The drain region 224 is laterally between the isolation structure 312 and the isolation structure 314. As shown in the layout of FIG. 2, the drain region 224 is generally rectangular. A width of the drain region 224 is less than and within the width of the n-type well 212, which widths are parallel to the channel width of the level-shift transistor (e.g., in y-directions).

A diffusion well 218 is disposed in the semiconductor substrate 302 (e.g., the epitaxial layer 306p). The diffusion well 218 extends from proximate the top major surface of the semiconductor substrate 302 to a depth less than a top of the n-type drift layer 210. The diffusion well 218 is laterally between the n-type wells 214, 216. The diffusion well 218 is laterally between the gate dielectric layer 322 and the isolation structure 316. As shown in the layout of FIG. 2, the diffusion well 218 is generally rectangular. A width of the diffusion well 218 is less than and within the width of the n-type drift layer 210, which widths are parallel to the channel width of the level-shift transistor (e.g., in y-directions). Further, the width of the diffusion well 218 is less than the width of the drain region 224.

A source region 226 and an integrated backgate region 228 are disposed in the semiconductor substrate 302 (e.g., the epitaxial layer 306p). The source region 226 and the integrated backgate region 228 are in the diffusion well 218 and extend from the top major surface of the semiconductor substrate 302 into the semiconductor substrate 302. The source region 226 and the integrated backgate region 228 are laterally between the gate dielectric layer 322 and the isolation structure 316. The source region 226 is laterally proximate to or at the gate dielectric layer 322, and the integrated backgate region 228 is laterally proximate to or at the isolation structure 316. As shown in the layout of FIG. 2, the source region 226 and the integrated backgate region 228 are generally rectangular. Respective widths of the source region 226 and the integrated backgate region 228 are less than and within the width of the diffusion well 218, which widths are parallel to the channel width of the level-shift transistor (e.g., in y-directions).

The n-type drift layer 210, n-type wells 212, 214, 216, drain region 224, and source region 226 are doped with a same dopant conductivity type (e.g., n-type), and the diffusion well 218 and integrated backgate region 228 are doped with a same opposite conductivity type (e.g., p-type).

In some examples, the n-type drift layer 210 may be an n-type layer doped with an n-type dopant at a concentration in a range from about 1×10¹⁷ cm⁻³ to about 2×10²⁰ cm⁻³. In some examples, the n-type wells 212, 214, 216 may each be an n-well doped with an n-type dopant at a concentration in a range from about 1×10¹⁷ cm⁻³ to about 2×10²⁰ cm⁻³. In some examples, the diffusion well 218 may be a p-well doped with a p-type dopant at a concentration in a range from about 1×10¹⁷ cm⁻³ to about 2×10²⁰ cm⁻³. In some examples, the drain region 224 and the source region 226 may each be n-doped with an n-type dopant at a concentration in a range from about 1×10²⁰ cm⁻³ to about 3×10²¹ cm⁻³, and the integrated backgate region 228 may be p-doped with a p-type dopant at a concentration in a range from about 1×10²⁰ cm⁻³ to about 3×10²¹ cm⁻³.

A gate electrode 220a, a gate-coupled field plate 220b, and drain-side field plates 222a, 222b are on or over the semiconductor substrate 302. The gate electrode 220a is on and over the gate dielectric layer 322 and the isolation structure 314. The gate electrode 220a is over the n-type well 214 and is proximate the diffusion well 218. The gate electrode 220a is laterally between the diffusion well 218 and the n-type well 212, and hence, is laterally between the source region 226 and the drain region 224.

The gate-coupled field plate 220b is on and over the isolation structure 316. The gate-coupled field plate 220b is laterally between the n-type well 216 and the anode region 208. The drain-side field plate 222a is on and over the isolation structure 314. The drain-side field plate 222a is laterally separated from the gate electrode 220a. The drain-side field plate 222a is laterally between the n-type well 214 and the n-type well 212. The drain-side field plate 222b is on and over the isolation structure 312. The drain-side field plate 222b is laterally between the n-type well 212 and the n-type well 204.

In the illustrated example, as shown in FIG. 2, the gate electrode 220a and gate-coupled field plate 220b are an integrated material(s) (e.g., in a rectangular shape), and the drain-side field plates 222a, 222b are an integrate material(s) (e.g., in an ovaloid shape or generally rectangular with rounded corners). A width of the gate electrode 220a is or is parallel to the channel width of the level-shift transistor (e.g., in a y-direction). The width of the gate electrode 220a is equal to the width of the n-type drift layer 210. The integrated material(s) of the gate electrode 220a and gate-coupled field plate 220b laterally encircle or encompass the diffusion well 218 and, hence, also the source region 226 and integrated backgate region 228. The integrated material(s) of the drain-side field plates 222a, 222b laterally encircle or encompass the n-type well 212 and, hence, also the drain region 224.

The gate electrode 220a, gate-coupled field plate 220b, and drain-side field plates 222a, 222b are or include a conductive material. In some examples, the gate electrode 220a, gate-coupled field plate 220b, and drain-side field plates 222a, 222b are or include doped polycrystalline silicon (polysilicon). In some examples, the gate electrode 220a, gate-coupled field plate 220b, and drain-side field plates 222a, 222b may be or include a metal. In other examples, the gate-coupled field plate 220b and drain-side field plates 222a, 222b may be in a metal layer over the semiconductor substrate 302 (e.g., in or over one or more dielectric layers).

The level-shift transistor (e.g., LDMOS transistor) includes the drain region 224, source region 226, n-type drift layer 210, n-type wells 212, 214, 216, diffusion well 218, and gate electrode 220a. The channel width of the level-shift transistor is in a direction perpendicular to a direction from the drain region 224 to the source region 226 (e.g., in a y-direction). A channel length of the level-shift transistor is in a direction from the drain region 224 to the source region 226 (e.g., in an x-direction). Hence, any direction parallel to the channel width is perpendicular to the channel length, and any direction parallel to the channel length is perpendicular to the channel width.

FIGS. 3 and 4 also show an n-type buried layer 330 that overlaps a portion of the n-type drift layer 202 and extends laterally from the n-type drift layer 202 into the high voltage device area 102. The n-type buried layer 330 may laterally extend throughout the high voltage device area 102, which, with the n-type well 204 in the junction diode area 106, may form a junction isolation tank. The junction isolation tank may colloquially be a “bathtub” in which one or more high voltage devices may be formed.

Referring back to FIG. 2, a proximal area 242 is near the transistor area 240 (e.g., generally neighboring the transistor area 240 in a y-direction), and a transition area 244 adjoins the proximal area 242. The proximal area 242 is between the transistor area 240 and the transition area 244. As detailed subsequently, the transition area 244 is defined by a reduction in a lateral dimension of the n-type drift layer 202 and/or in a lateral distance between the cathode region 206 and a lateral edge of the n-type drift layer 202.

The cathode region 206 includes a first linear cathode segment 206a in the transistor area 240, a conformal cathode segment 206b at a transition from the transistor area 240 to the proximal area 242, and a second linear cathode segment 206c in the proximal area 242 and the transition area 244 and extending laterally from the transition area 244. The first linear cathode segment 206a extends linearly laterally parallel to the channel width and perpendicular to the channel length of the level-shift transistor. The conformal cathode segment 206b extends from the first linear cathode segment 206a and conforms laterally to the periphery of the level-shift transistor (e.g., corresponding to the rounded corners of the n-type drift layer 210 and integrated material(s) of the drain-side field plate 222b). The second linear cathode segment 206c extends from the conformal cathode segment 206b and linearly laterally parallel to the channel width and perpendicular to the channel length of the level-shift transistor.

The anode region 208 includes a first linear anode segment 208a in the transistor area 240 and the proximal area 242 and extending into the transition area 244, a second linear anode segment 208b in the transition area 244, and a third linear anode segment 208c extending laterally from the transition area 244. The first linear anode segment 208a extends linearly laterally parallel to the channel width and perpendicular to the channel length of the level-shift transistor. The first linear anode segment 208a, as illustrated, extends into the transition area 244 by a first lateral distance 246 from the proximal area 242. Other examples may omit such a first lateral distance 246 such that the first linear anode segment 208a does not extend into the transition area 244. The second linear anode segment 208b extends from the first linear anode segment 208a and linearly laterally non-parallel and non-perpendicular to the channel width and the channel length of the level-shift transistor. In a direction perpendicular to the channel length and parallel to the channel width (e.g., in a y-direction), the second linear anode segment 208b extends laterally a first lateral dimension 248. The first linear anode segment 208a of the anode region 208 forms a first angle 250 with the second linear anode segment 208b of the anode region 208. The first angle 250 is less than 180° and may be in a range from 90° to 170°. The third linear anode segment 208c extends from the second linear anode segment 208b and linearly laterally parallel to the channel width and perpendicular to the channel length of the level-shift transistor.

A second lateral distance 252 is between the first linear anode segment 208a of the anode region 208 and the second linear cathode segment 206c of the cathode region 206 in the proximal area 242 and the transition area 244. A lateral distance between the second linear anode segment 208b of the anode region 208 and the second linear cathode segment 206c of the cathode region 206 (e.g., illustrated by a third lateral distance 254) decreases in the transition area 244 in a direction away from the proximal area 242. A fourth lateral distance 256 is between the third linear anode segment 208c of the anode region 208 and the second linear cathode segment 206c of the cathode region 206 extending away from the transition area 244. The second lateral distance 252, third lateral distance 254, and fourth lateral distance 256 are perpendicular to the channel width and parallel to the channel length of the level-shift transistor (e.g., in x-directions).

A first lateral distance reduction is a reduction of a distance between the second linear anode segment 208b of the anode region 208 and the second linear cathode segment 206c of the cathode region 206 from proximate the level-shift transistor to distal from the level-shift transistor. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor. In some examples, a ratio of the first lateral dimension 248 to the first lateral distance reduction is in a range from 0 to 5.67. In some examples, a ratio of the fourth lateral distance 256 to the second lateral distance 252 is in a range from 1:7 to 1:1.2.

The n-type drift layer 202 includes a first linear drift portion 202a in the transistor area 240, a conformal drift portion 202b at a transition from the transistor area 240 to the proximal area 242, a proximal drift portion 202c in the proximal area 242, a transition drift portion 202d in the transition area 244, and a second linear drift portion 202e extending laterally from the transition area 244. The first linear drift portion 202a extends linearly laterally parallel to the channel width and perpendicular to the channel length of the level-shift transistor. The conformal drift portion 202b extends from the first linear drift portion 202a and conforms laterally to the periphery of the level-shift transistor (e.g., corresponding rounded corners of the n-type drift layer 210 and integrated material(s) of the drain-side field plate 222b).

The proximal drift portion 202c extends from the conformal drift portion 202b. The proximal drift portion 202c has a first lateral edge, at which a first p-n junction 260 is formed, proximate to the first linear anode segment 208a of the anode region 208. The first lateral edge, and hence, the first p-n junction 260, extends linearly in a direction parallel to the channel width and perpendicular to the channel length of the level-shift transistor. The first p-n junction 260 is formed at the first lateral edge of the n-type drift layer 202 in the epitaxial layer 306p.

The transition drift portion 202d extends from the proximal drift portion 202c. The transition drift portion 202d has a third lateral dimension 262 in a direction parallel to the channel width and perpendicular to the channel length of the level-shift transistor. The transition drift portion 202d has a second lateral edge, at which a second p-n junction 264 is formed, proximate to the first linear anode segment 208a and/or second linear anode segment 208b of the anode region 208. The second lateral edge, and hence, the second p-n junction 264, extends linearly in a direction non-parallel and non-perpendicular to the channel width and the channel length of the level-shift transistor. The second p-n junction 264 is formed at the second lateral edge of the n-type drift layer 202 in the epitaxial layer 306p. The second lateral edge (e.g., at the second p-n junction 264) of the transition drift portion 202d forms a second angle 266 with the first lateral edge (e.g., at the first p-n junction 260) of the proximal drift portion 202c. The second angle 266 is formed laterally interior to the n-type drift layer 202. The second angle 266 is less than 180° and may be in a range from 90° to 170°. In some examples, the first angle 250 formed by the anode region 208 is less than the second angle 266 formed by the n-type drift layer 202.

The second linear drift portion 202e extends from the transition drift portion 202d and linearly laterally parallel to the channel width and perpendicular to the channel length of the level-shift transistor. The second linear drift portion 202e has a third lateral edge, at which a third p-n junction 268 is formed, proximate to the second linear anode segment 208b and/or third linear anode segment 208c of the anode region 208. The third lateral edge, and hence, the third p-n junction 268, extends linearly in a direction parallel to the channel width and perpendicular to the channel length of the level-shift transistor. The third p-n junction 268 is formed at the third lateral edge of the n-type drift layer 202 in the epitaxial layer 306p.

Generally, for each of the first linear drift portion 202a, the conformal drift portion 202b, and the second linear drift portion 202e, a respective uniform distance is between the cathode region 206 and a lateral edge of the respective drift portion 202a, 202b, 202e proximate to the anode region 208, where the respective uniform lateral distance is perpendicular to an instantaneous direction of lateral extension (e.g., a tangent line) of the corresponding portion of the cathode region 206. The respective lateral distances of the drift portions 202a, 202b, 202e may be an equal lateral distance. The lateral distances for the first linear drift portion 202a and the second linear drift portion 202e are parallel to the channel length and perpendicular to the channel width of the level-shift transistor (e.g., in x-directions). The lateral distance of the conformal drift portion 202b is non-parallel and non-perpendicular to the channel length and the channel width.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the second lateral edge (e.g., at the second p-n junction 264) and the second linear cathode segment 206c of the cathode region 206 decreases (e.g., relative to the fifth lateral distance 272) in the transition area 244 in a direction away from the proximal area 242. A seventh lateral distance 276 is between the third lateral edge (e.g., at the third p-n junction 268) and the second linear cathode segment 206c of the cathode region 206. The fifth lateral distance 272, sixth lateral distance 274, and seventh lateral distance 276 are perpendicular to the channel width and parallel to the channel length of the level-shift transistor (e.g., in x-directions). As illustrated, the transition drift portion 202d has a lateral dimension that reduces resulting in a reduction of a lateral distance (between the second lateral edge (e.g., at the second p-n junction 264) and the cathode region 206) from the fifth lateral distance 272 in the transition area 244 proximate to the level-shift transistor to the seventh lateral distance 276 in the transition area 244 distal from the level-shift transistor.

A second lateral distance reduction is a reduction of a distance between the second lateral edge (e.g., at the second p-n junction 264) and the second linear cathode segment 206c of the cathode region 206 from proximate the level-shift transistor to distal from the level-shift transistor. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the first linear anode segment 208a of the anode region 208 and the first lateral edge (e.g., at the first p-n junction 260) of the proximal drift portion 202c of the n-type drift layer 202 in the proximal area 242. A lateral distance between the second linear anode segment 208b of the anode region 208 and the second lateral edge (e.g., at the second p-n junction 264) of the transition drift portion 202d of the n-type drift layer 202 (e.g., illustrated by a ninth lateral distance 284) decreases in the transition area 244 in a direction away from the proximal area 242. A tenth lateral distance 286 is between the third linear anode segment 208c of the anode region 208 and the third lateral edge (e.g., at the third p-n junction 268) of the second linear drift portion 202e of the n-type drift layer 202 extending away from the transition area 244. The eighth lateral distance 282, ninth lateral distance 284, and tenth lateral distance 286 are perpendicular to the channel width and parallel to the channel length of the level-shift transistor (e.g., in x-directions).

A third lateral distance reduction is a reduction of a distance between the first linear anode segment 208a and/or second linear anode segment 208b of the anode region 208 and the second lateral edge (e.g., at the second p-n junction 264) from proximate the level-shift transistor to distal from the level-shift transistor. The third lateral distance reduction is the difference between the eighth lateral distance 282 and the tenth lateral distance 286. The third lateral distance reduction is in a direction (e.g., in an x-direction) parallel to the channel length and perpendicular to the channel width of the level-shift transistor. In some examples, a ratio of the tenth lateral distance 286 to the eighth lateral distance 282 is in a range from 1:7 to 1:1.2.

Due to the extension of the first linear anode segment 208a into the transition area 244 by the first lateral distance 246 in some examples, the lateral distance between the anode region 208 and the second linear cathode segment 206c of the cathode region 206 may initially stay the same from the boundary between the proximal area 242 and the transition area 244 before decreasing in the transition area 244 in a direction away from the proximal area 242. Also, the lateral distance between the anode region 208 and the second lateral edge (e.g., at the second p-n junction 264) of the transition drift portion 202d of the n-type drift layer 202 may initially increase from the boundary between the proximal area 242 and the transition area 244 before decreasing in the transition area 244 in a direction away from the proximal area 242.

As described, a lateral distance (e.g., the sixth lateral distance 274) between the cathode region 206 and a second lateral edge (e.g., at the second p-n junction 264) of the n-type drift layer 202 proximate the anode region 208 decreases from proximate the level-shift transistor to distal from the level-shift transistor. The lateral distance is parallel to the channel length and perpendicular to the channel width of the level-shift transistor. The cathode region 206 (e.g., the second linear cathode segment 206c) extends in a direction perpendicular to the channel length and parallel to the channel width corresponding to where (e.g., in the transition area 244) the lateral distance (e.g., the sixth lateral distance 274) decreases from proximate the level-shift transistor to distal from the level-shift transistor. The anode region 208 (e.g., the second linear anode segment 208b) extends laterally in a direction non-parallel and/or non-perpendicular to the channel width and/or the channel length corresponding to where (e.g., in the transition area 244) the lateral distance (e.g., the sixth lateral distance 274) decreases from proximate the level-shift transistor to distal from the level-shift transistor.

A lateral distance (e.g., the third lateral distance 254) between the anode region 208 and the cathode region 206 decreases from proximate the level-shift transistor to distal from the level-shift transistor corresponding, at least in part, to where (e.g., in the transition area 244) the lateral distance (e.g., the sixth lateral distance 274) decreases from proximate the level-shift transistor to distal from the level-shift transistor. A lateral distance (e.g., the ninth lateral distance 284) between the anode region 208 and the n-type drift layer 202 decreases from proximate the level-shift transistor to distal from the level-shift transistor corresponding, at least in part, to where (e.g., in the transition area 244) the lateral distance (e.g., the sixth lateral distance 274) decreases from proximate the level-shift transistor to distal from the level-shift transistor.

Similarly, a lateral distance (e.g., the third lateral distance 254) between the anode region 208 and the cathode region 206 decreases as the anode region 208 extends laterally non-parallel and non-perpendicular to the channel width and/or channel length (e.g., in the transition area 244). The cathode region 206 extends in a direction parallel to the channel width and perpendicular to the channel length corresponding to where (e.g., in the transition area 244) the anode region 208 extends laterally non-parallel and non-perpendicular to the channel width and/or channel length distally away from the level-shift transistor.

The n-type drift layer 210 of the level-shift transistor has a fourth lateral dimension 292 parallel to the channel length and perpendicular to the channel width of the level-shift transistor (e.g., in an x-direction). The proximal drift portion 202c of the n-type drift layer 202 laterally overlaps in directions parallel to the channel width and perpendicular to the channel length (e.g., in y-directions) the n-type drift layer 210 of the level-shift transistor by an overlapping lateral dimension 294. The n-type drift layer 210 of the level-shift transistor does not laterally overlap in directions parallel to the channel width and perpendicular to the channel length (e.g., in y-directions) the proximal drift portion 202c of the n-type drift layer 202 by a non-overlapping lateral dimension 296. The overlapping lateral dimension 294 and the non-overlapping lateral dimension 296 are in directions parallel to the channel length and perpendicular to the channel width (e.g., in x-directions). In some examples, the overlapping lateral dimension 294 is equal to or greater than 33% of the fourth lateral dimension 292 of the n-type drift layer 210 (e.g., for a lower voltage rating), which percentage may be increased for a higher voltage rating. In some examples, the non-overlapping lateral dimension 296 is equal to or less than 66% of the fourth lateral dimension 292 of the n-type drift layer 210 (e.g., for a lower voltage rating), which percentage may be decreased for a higher voltage rating.

By laterally overlapping the n-type drift layer 210 with the proximal drift portion 202c of the n-type drift layer 210, electric fields in the semiconductor substrate 302 may be relatively smooth between the level-shift transistor and the diode (e.g., in the n-type drift layers 202, 210). These electric fields may occur when a high voltage is applied to the drain region 224 and the cathode region 206 and a low voltage is applied to the source region 226 and the anode region 208. Reducing the lateral distance between the second lateral edge (e.g., at the second p-n junction 264) of the n-type drift layer 202 in the transition area 244 permits the lateral distance between the cathode region 206 and the anode region 208 to be reduced. Reducing the distance between the cathode region 206 and the anode region 208 permits the diode to have a lower breakdown voltage. The lower breakdown voltage of the diode may permit voltage clamping during an ESD event to be performed by the diode rather than the level-shift transistor. Because the diode has a larger area throughout the junction diode area 106, the diode may be more robust for discharging the ESD event and may have larger current capacity to discharge the ESD event. Further, by reducing the lateral distance, the junction diode area 106 may consume less area on the IC die, which may permit more devices to be formed on the IC die and may permit area of the IC die to be used more efficiently.

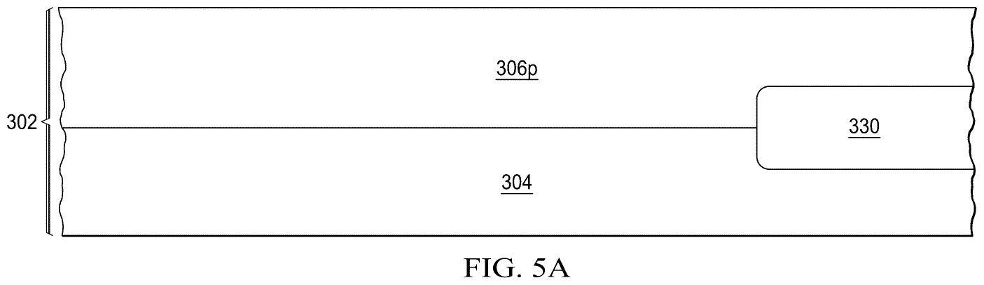

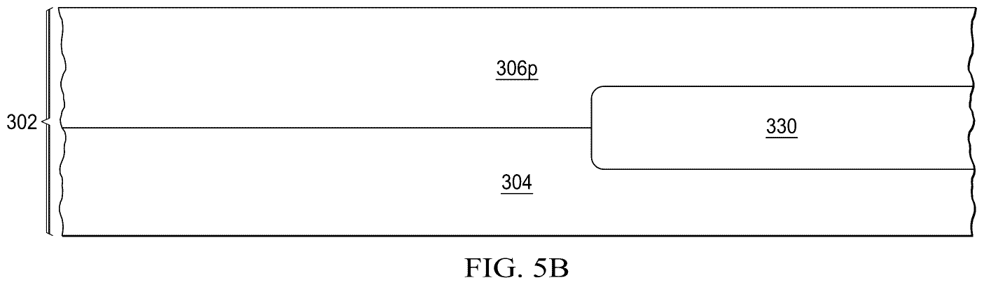

FIGS. 5A and 5B through FIGS. 11A and 11B illustrate cross-sectional views of the IC die of FIGS. 1, 2, 3, and 4 at various stages of manufacturing according to an example method. Figures ending in an “A” designation correspond with the cross-section 3-3 in the layout of FIG. 2, which is illustrated in the cross-sectional view of FIG. 3. Figures ending in a “B” designation correspond with the cross-section 4-4 in the layout of FIG. 2, which is illustrated in the cross-sectional view of FIG. 4.

To avoid unnecessary repetition, doped buried layers, wells, and regions are formed by implanting a dopant into the semiconductor substrate 302. To form a doped buried layer, a well, or a doped region by implantation, a photoresist may be deposited (e.g., by spin-on) on or over the semiconductor substrate 302 and patterned using photolithography to expose the area corresponding to where the doped buried layer, well, or doped region is to be formed (e.g., like in the layout of FIG. 2). Using the patterned photoresist as a mask, an implant is performed to implant the dopant into the semiconductor substrate 302 thereby forming the doped buried layer, well, or doped region. After the implant, the photoresist may be removed, such as by a wet strip or ashing. Examples of dopant types and concentrations of various doped buried layers, wells, and doped regions described in FIGS. 5A and 5B through FIGS. 11A and 11B are as described above.

Referring to FIGS. 5A and 5B, an epitaxial layer 306p is formed on or over the semiconductor support substrate 304. The epitaxial layer 306p may be formed by an appropriate epitaxial growth process, such as low pressure chemical vapor deposition (LPCVD) or the like. The epitaxial layer 306p is doped, such as by in situ doping during the epitaxial growth. The dopant type and concentration of the epitaxial layer 306p are as described above. In the illustrated example, the semiconductor support substrate 304 and the epitaxial layer 306p form a semiconductor substrate 302. In other examples, another semiconductor substrate may be used. For example, the semiconductor substrate 302 may be a bulk silicon wafer (e.g., without the epitaxial layer 306p). An n-type buried layer 330 is formed in the semiconductor substrate 302. The n-type buried layer 330 may be formed by implanting dopants into the epitaxial layer 306p.

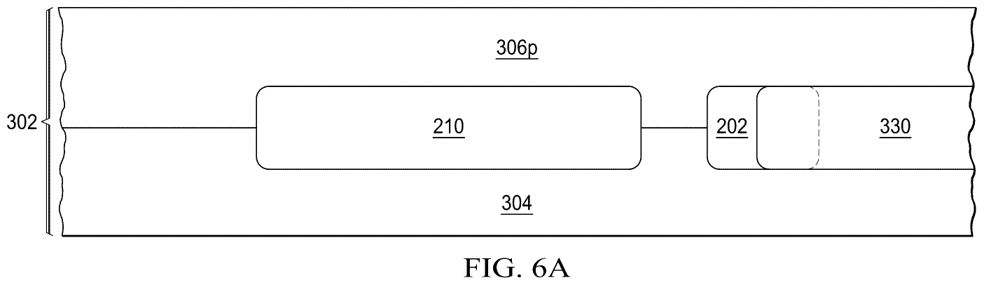

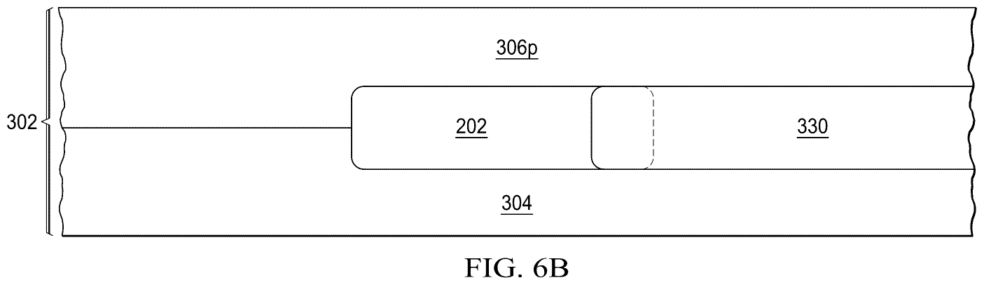

Referring to FIGS. 6A and 6B, n-type drift layers 202, 210 are formed in the semiconductor substrate 302. The n-type drift layers 202, 210 may be formed by implanting dopants into the epitaxial layer 306p.

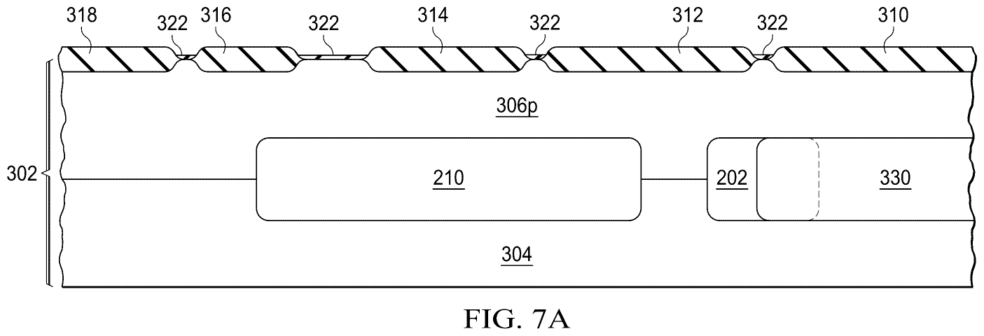

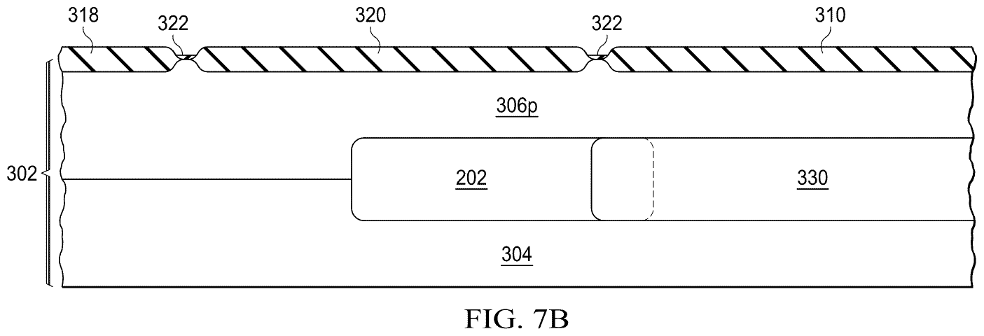

Referring to FIGS. 7A and 7B, isolation structures 310-320 and a gate dielectric layer 322 are formed at or on the top major surface of the semiconductor substrate 302. The gate dielectric layer 322 may be formed by an oxidation process, such as in situ steam generation (ISSG) oxidation, thermal oxidation, or the like. Then, a mask layer may be deposited over the gate dielectric layer 322, such as by a chemical vapor deposition (CVD). The mask layer may be, for example, silicon nitride or another material having etch selectivity to the gate dielectric layer 322. The mask layer may then be patterned, such as by using appropriate photolithography and etch processes. The patterned mask layer has openings corresponding to where the isolation structures 310-320 are to be formed. An oxidation process, such as ISSG oxidation, thermal oxidation, or the like, is performed to form the isolation structures 310-320 at the openings of the mask layer. The mask layer may then be removed, such as by a wet etch selective to the material of the mask layer. In some examples, instead of forming the gate dielectric layer 322, another dielectric layer, such as a pad oxide layer, may be formed, where the mask layer is formed over the other dielectric layer. That other dielectric layer may be removed in subsequent processing with the gate dielectric layer 322 being formed thereafter and before formation of a gate electrode.

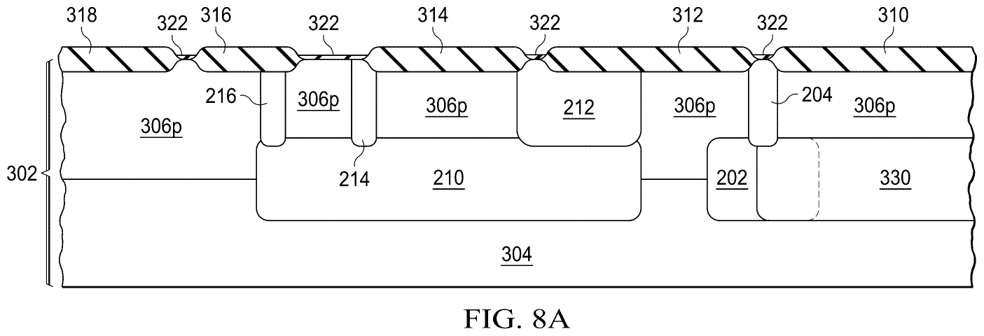

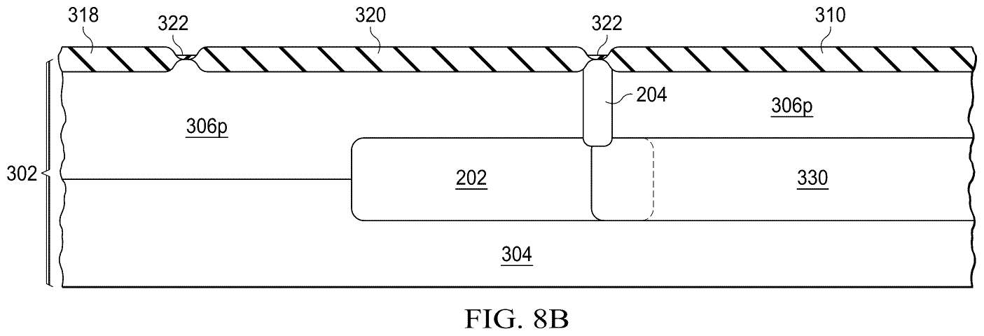

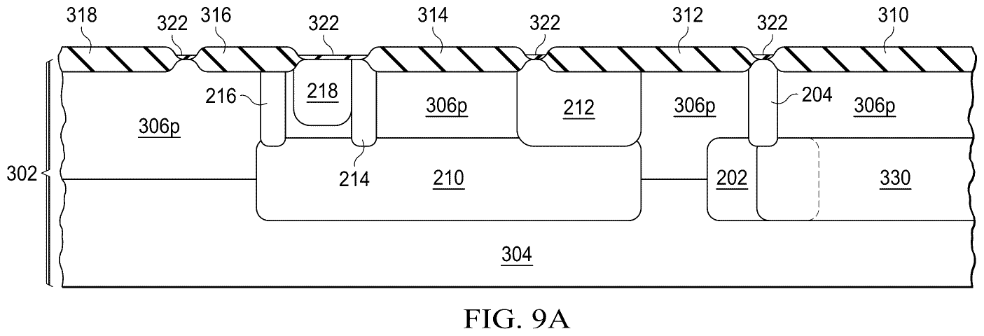

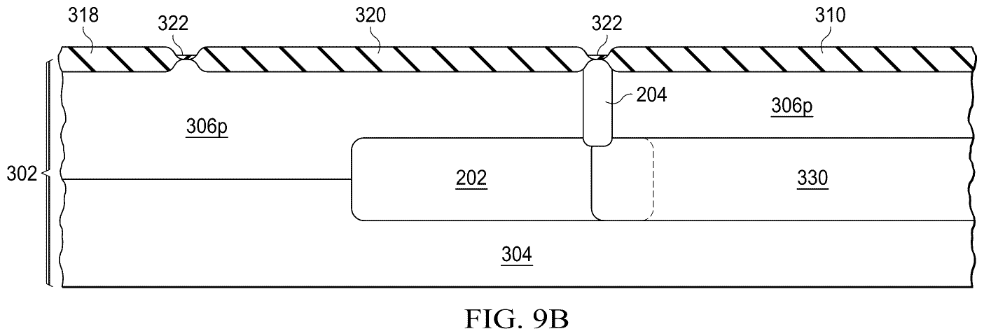

Referring to FIGS. 8A and 8B, n-type wells 204, 212, 214, 216 are formed in the semiconductor substrate 302. The n-type wells 204, 212, 214, 216 may be formed by implanting dopants into the epitaxial layer 306p. Referring to FIGS. 9A and 9B, a diffusion well 218 is formed in the semiconductor substrate 302. The a diffusion well 218 may be formed by implanting dopants into the epitaxial layer 306p.

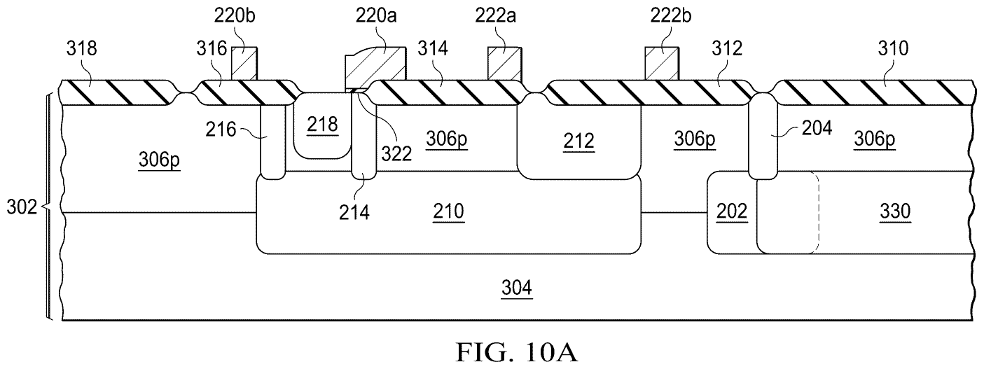

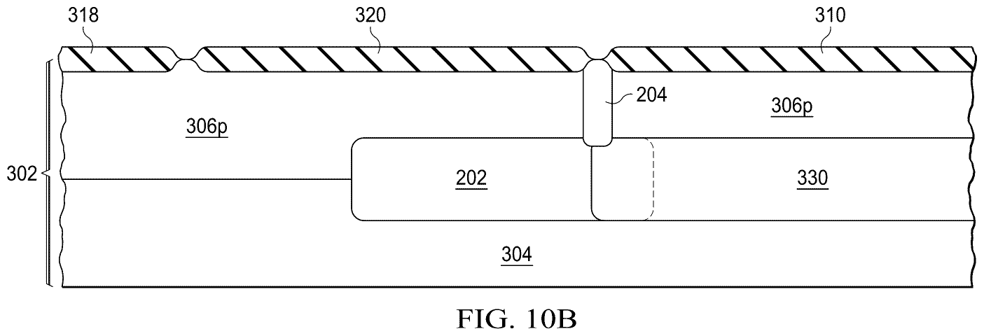

Referring to FIGS. 10A and 10B, a gate electrode 220a, a gate-coupled field plate 220b, and drain-side field plates 222a, 222b are formed over the semiconductor substrate 302. A material(s) of the gate electrode 220a, gate-coupled field plate 220b, and drain-side field plates 222a, 222b may be deposited over the semiconductor substrate 302 (e.g., on and over the isolation structures 310-320 and the gate dielectric layer 322), such as by CVD, physical vapor deposition (PVD), or the like. The material(s) may then be patterned into the gate electrode 220a, gate-coupled field plate 220b, and drain-side field plates 222a, 222b using appropriate photolithography and etch processes. Patterning the material(s) may also pattern the gate dielectric layer 322 such that the gate dielectric layer 322 remains under the gate electrode 220a and is removed from other areas of the semiconductor substrate 302.

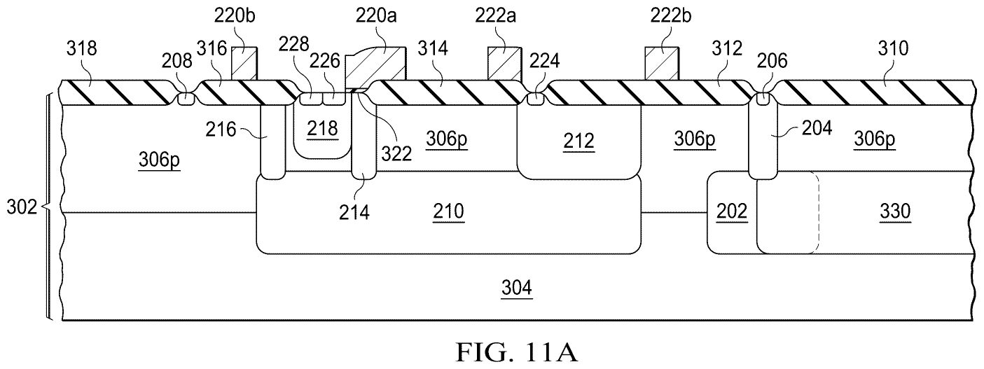

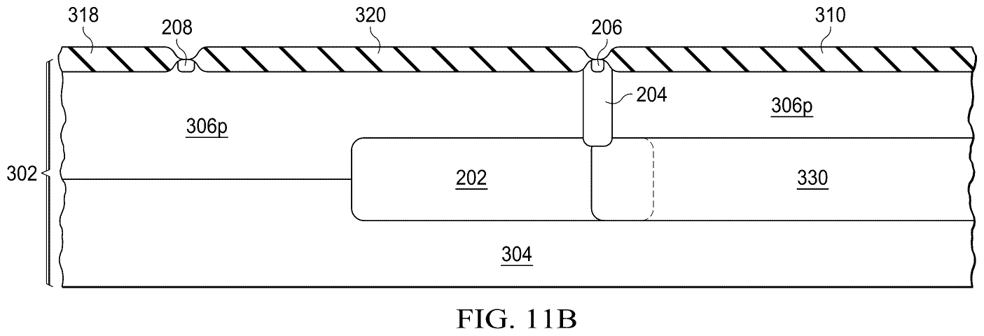

Referring to FIGS. 11A and 11B, a cathode region 206, drain region 224, and source region 226 are formed in the semiconductor substrate 302. The cathode region 206, drain region 224, and source region 226 may be formed by implanting dopants into the epitaxial layer 306p. Also, an anode region 208 and an integrated backgate region 228 are formed in the semiconductor substrate 302. The anode region 208 and integrated backgate region 228 may be formed by implanting dopants into the epitaxial layer 306p.

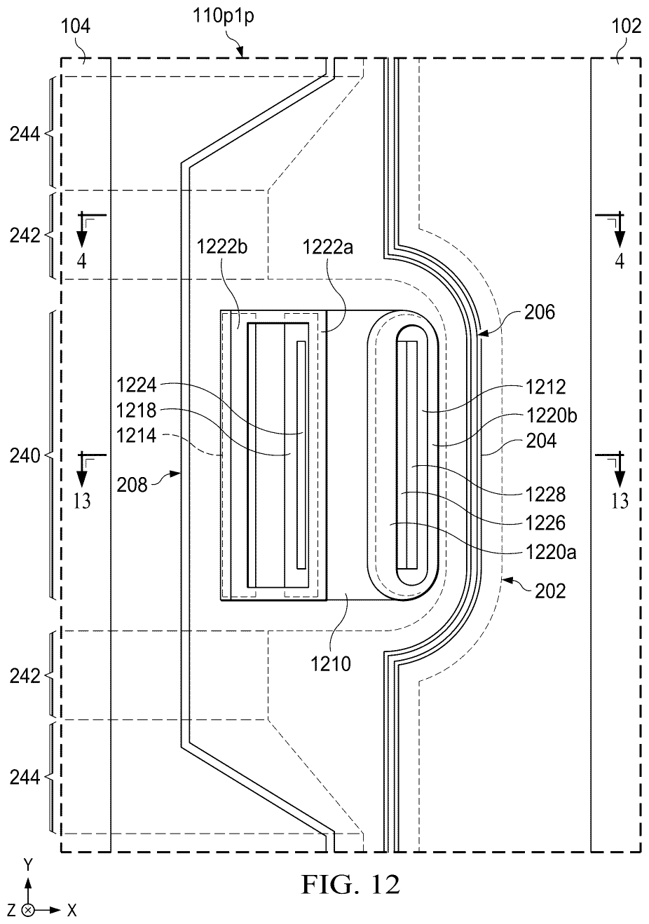

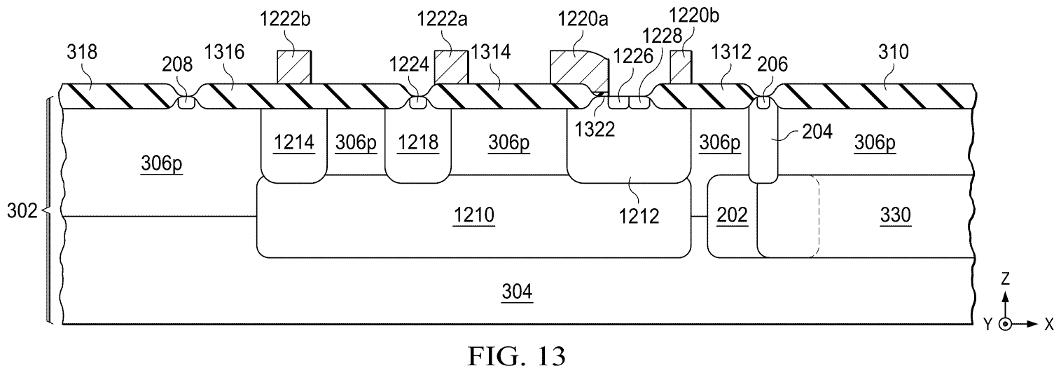

FIG. 12 is a layout of an inset 110p1p as an example of the inset 110 of FIG. 1 according to some examples. FIG. 12 shows a cross-section 13-13 and a cross-section 4-4. FIG. 13 shows a cross-sectional view of the cross-section 13-13 of FIG. 12, and FIG. 4 shows the cross-sectional view of the cross-section 4-4 of FIG. 12. In FIGS. 12, 13, and 4, the level-shift transistor is a p-type LDMOS transistor in a p-type epitaxial layer (or more generally, semiconductor substrate), as will be detailed subsequently.

The layout of FIG. 12 is in and/or on a semiconductor substrate 302, which is shown in FIGS. 4 and 13. The semiconductor substrate 302, in the illustrated examples, includes a semiconductor support substrate 304 and an epitaxial layer 306p. The semiconductor substrate 302, including the epitaxial layer 306p, may be as described above. FIG. 13 also shows isolation structures 310, 1312, 1314, 1316, 318 at the top major surface of the semiconductor substrate 302, which are like the isolation structures 310-318 described above, except with a different arrangement. A gate dielectric layer 1322 is at the top the top major surface of the semiconductor substrate 302, which is like the gate dielectric layer 322 described above except extending from isolation structure 1314 as described in more detail subsequently.

Referring to FIGS. 12, 13, and 4, the diode includes the cathode region 206, n-type well 204, n-type drift layer 202, and anode region 208 as described above with respect to FIGS. 2, 3, and 4. Although not illustrated in FIG. 12, the n-type drift layer 202 includes the first linear drift portion 202a, conformal drift portion 202b, proximal drift portion 202c, transition drift portion 202d, and second linear drift portion 202e. The cathode region 206 includes the first linear cathode segment 206a, conformal cathode segment 206b, and second linear cathode segment 206c. The anode region 208 includes the first linear anode segment 208a, second linear anode segment 208b, third linear anode segment 208c. The relationships between the cathode region 206, n-type well 204, n-type drift layer 202, and/or anode region 208 are as described above, although not illustrated in FIG. 12.

The level-shift transistor is laterally between the cathode region 206 and the anode region 208 in a transistor area 240 shown in FIG. 12, which includes the cross-section 13-13 of FIG. 13. Components of the level-shift transistor have a generally rectangular shape (e.g., including a rectangular shape with two or four rounded corners) in the layout view of FIG. 12.

Referring to FIGS. 12 and 13, an n-type drift layer 1210 is disposed in the semiconductor substrate 302 (e.g., the epitaxial layer 306p and the semiconductor support substrate 304). The n-type drift layer 1210 in the illustrated example is a buried layer. The n-type drift layer 1210 is at a depth in the semiconductor substrate 302 that is generally the same depth of the n-type drift layer 202. The n-type drift layer 1210 is laterally separated from the n-type drift layer 202. The n-type drift layer 1210 extends laterally from under the isolation structure 1312 to under the isolation structure 1316, including under the isolation structure 1314. The n-type drift layer 1210, as illustrated in FIG. 12, is generally rectangular with rounded corners proximate the cathode region 206 of the diode.

N-type wells 1212, 1214 are disposed in the semiconductor substrate 302 (e.g., the epitaxial layer 306p). The n-type wells 1212, 1214 each extend from proximate the top major surface of the semiconductor substrate 302 to and contacting the n-type drift layer 1210. The n-type well 1212 extends from under the isolation structure 1312 (e.g., from a same lateral location as the n-type drift layer 1210) to under the gate dielectric layer 1322 and the isolation structure 1314. The n-type well 1214 is under the isolation structure 1316. As shown in the layout of FIG. 12, the n-type well 1212 is generally rectangular with four rounded corners, and the n-type well 1214 is generally rectangular. Respective widths of the n-type wells 1212, 1214 are equal to and co-extensive with a width of the n-type drift layer 1210, which widths are parallel to a channel width (indicated subsequently) of the level-shift transistor (e.g., in y-directions).

A p-type well 1218 is disposed in the semiconductor substrate 302 (e.g., the epitaxial layer 306p). The p-type well 1218 extends from proximate the top major surface of the semiconductor substrate 302 to and contacting the n-type drift layer 1210. The p-type well 1218 is laterally between the n-type wells 1212, 1214. The p-type well 1218 is laterally between the isolation structure 1314 and the isolation structure 1316. As shown in the layout of FIG. 12, the p-type well 1218 is generally rectangular. A width of the p-type well 1218 is less than and within the width of the n-type drift layer 1210, which widths are parallel to the channel width of the level-shift transistor (e.g., in y-directions).

A drain region 1224 is disposed in the semiconductor substrate 302 (e.g., the epitaxial layer 306p). The drain region 1224 is in the p-type well 1218 and extends from the top major surface of the semiconductor substrate 302 into the semiconductor substrate 302. The drain region 1224 is laterally between the isolation structure 1314 and the isolation structure 1316. As shown in the layout of FIG. 12, the drain region 1224 is generally rectangular. A width of the drain region 1224 is less than and within the width of the p-type well 1218, which widths are parallel to the channel width of the level-shift transistor (e.g., in y-directions).

A source region 1226 and an integrated backgate region 1228 are disposed in the semiconductor substrate 302 (e.g., the epitaxial layer 306p). The source region 1226 and the integrated backgate region 1228 are in the n-type well 1212 and extend from the top major surface of the semiconductor substrate 302 into the semiconductor substrate 302. The source region 1226 and the integrated backgate region 1228 are laterally between the gate dielectric layer 1322 and the isolation structure 1312. The source region 1226 is laterally proximate to or at the gate dielectric layer 1322, and the integrated backgate region 1228 is laterally proximate to or at the isolation structure 1312. As shown in the layout of FIG. 12, the source region 1226 and the integrated backgate region 1228 are generally rectangular. Respective widths of the source region 1226 and the integrated backgate region 1228 are less than and within the width of the n-type well 1212, which widths are parallel to the channel width of the level-shift transistor (e.g., in y-directions). Additionally, respective widths of the source region 1226 and the integrated backgate region 1228 are less than the width of the drain region 1224.

The n-type drift layer 1210, n-type wells 1212, 1214, and integrated backgate region 1228 are doped with a same dopant conductivity type (e.g., n-type), and the p-type well 1218, drain region 1224, and source region 1226 are doped with a same opposite conductivity type (e.g., p-type).

In some examples, the n-type drift layer 1210 may be an n-type layer doped with an n-type dopant at a concentration in a range from about 1×10¹⁷ cm⁻³ to about 2×10²⁰ cm⁻³. In some examples, the n-type wells 1212, 1214 may each be an n-well doped with an n-type dopant at a concentration in a range from about 1×10¹⁷ cm⁻³ to about 2×10²⁰ cm⁻³. In some examples, the p-type well 1218 may be a p-well doped with a p-type dopant at a concentration in a range from about 1×10¹⁷ cm⁻³ to about 2×10²⁰ cm⁻³. In some examples, the drain region 1224 and the source region 1226 may each be p-doped with a p-type dopant at a concentration in a range from about 1×10²⁰ cm⁻³ to about 3×10²¹ cm⁻³, and the integrated backgate region 1228 may be n-doped with an n-type dopant at a concentration in a range from about 1×10²⁰ cm⁻³ to about 3×10²¹ cm⁻³.

A gate electrode 1220a, a gate-coupled field plate 1220b, and drain-side field plates 1222a, 1222b are on or over the semiconductor substrate 302. The gate electrode 1220a, gate-coupled field plate 1220b, and drain-side field plates 1222a, 1222b are like the gate electrode 220a, gate-coupled field plate 220b, and drain-side field plates 222a, 222b, respectively, described above, except arranged differently. The gate electrode 1220a is on and over the gate dielectric layer 1322 and the isolation structure 1314. The gate electrode 1220a is over the n-type well 1212. The gate electrode 1220a is laterally between the source region 1226 and the drain region 1224.

The gate-coupled field plate 1220b is on and over the isolation structure 1312. The gate-coupled field plate 1220b is over the n-type well 1212 proximate to the cathode region 206. The drain-side field plate 1222a is on and over the isolation structure 1314. The drain-side field plate 1222a is laterally separated from the gate electrode 1220a. The drain-side field plate 1222a is over the p-type well 1218. The drain-side field plate 1222b is on and over the isolation structure 1316 and over the n-type well 1214.

In the illustrated example, as shown in FIG. 12, the gate electrode 1220a and gate-coupled field plate 1220b are an integrated material(s) (e.g., in an ovaloid shape or generally rectangular with rounded corners), and the drain-side field plates 1222a, 1222b are an integrate material(s) (e.g., in a rectangular shape). A width of the gate electrode 1220a is or is parallel to the channel width of the level-shift transistor (e.g., in a y-direction). The width of the gate electrode 1220a is equal to the width of the n-type drift layer 1210. The integrated material(s) of the gate electrode 1220a and gate-coupled field plate 1220b laterally encircle or encompass the n-type well 1212 and, hence, also the source region 1226 and integrated backgate region 1228. The integrated material(s) of the drain-side field plates 1222a, 1222b laterally encircle or encompass the p-type well 1218 and, hence, also the drain region 1224.

The level-shift transistor (e.g., LDMOS transistor) includes the drain region 1224, source region 1226, n-type drift layer 1210, n-type wells 1212, 1214, p-type well 1218, and gate electrode 1220a. The channel width of the level-shift transistor is in a direction perpendicular to a direction from the drain region 1224 to the source region 1226 (e.g., in a y-direction). A channel length of the level-shift transistor is in a direction from the drain region 1224 to the source region 1226 (e.g., in an x-direction). Hence, any direction parallel to the channel width is perpendicular to the channel length, and any direction parallel to the channel length is perpendicular to the channel width.

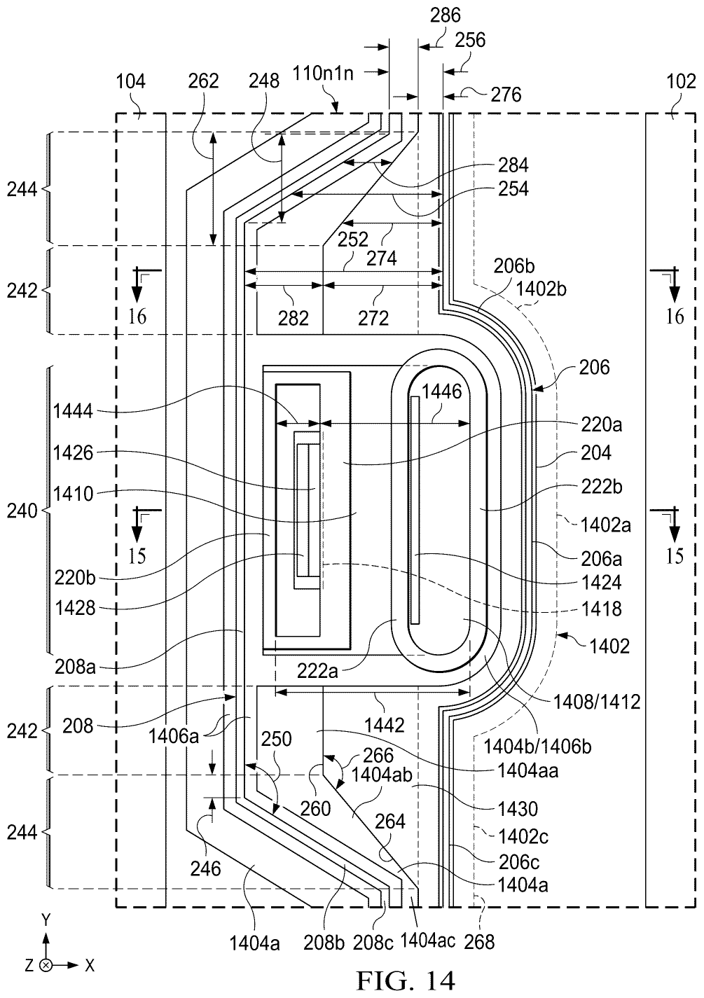

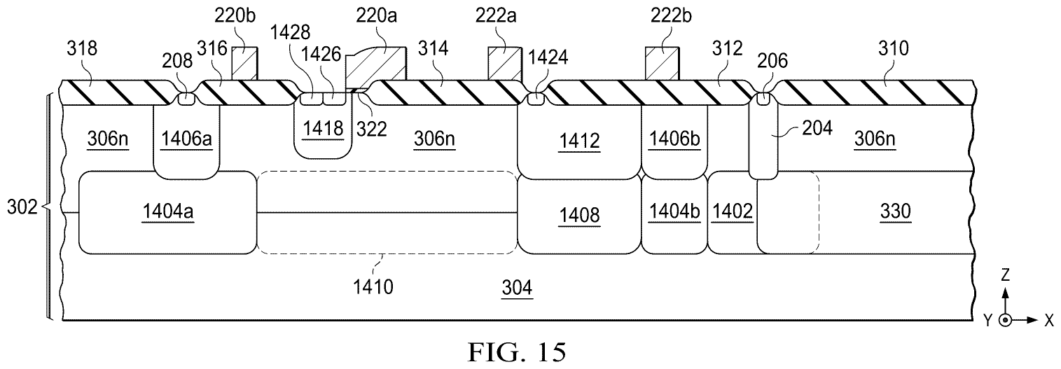

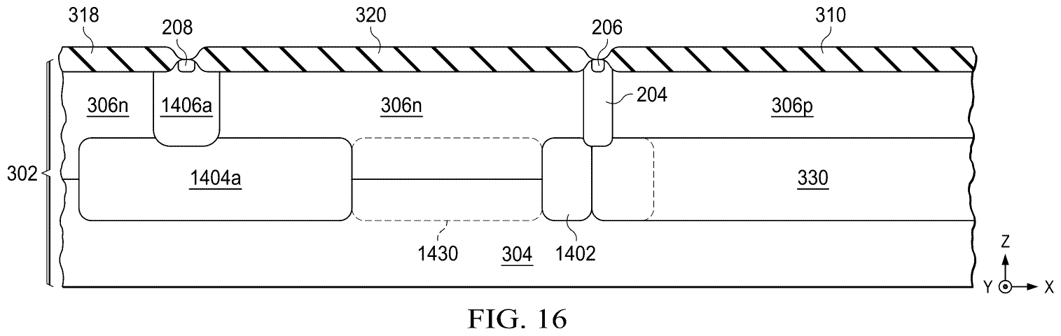

FIG. 14 is a layout of an inset 110n1n as an example of the inset 110 of FIG. 1 according to some examples. FIG. 14 shows a cross-section 15-15 and a cross-section 16-16. FIG. 15 shows a cross-sectional view of the cross-section 15-15 of FIG. 14, and FIG. 16 shows a cross-sectional view of the cross-section 16-16 of FIG. 14. FIGS. 14, 15, and 16 are described together. FIGS. 14, 15, and 16 also show X-Y-Z axes for orienting the figures relative to each other. In FIGS. 14, 15, and 16, the level-shift transistor is an n-type LDMOS transistor in an n-type epitaxial layer (or more generally, semiconductor substrate), as will be detailed subsequently.

The layout of FIG. 14 is in and/or on a semiconductor substrate 302, which is shown in FIGS. 15 and 16. The semiconductor substrate 302, in the illustrated examples, includes a semiconductor support substrate 304 and an epitaxial layer 306n. The semiconductor substrate 302 may be as described above, except that the semiconductor material of the semiconductor substrate 302 (e.g., the epitaxial layer 306n) is n-doped with an n-type dopant, which may be at a same concentration as the p-type dopant of the epitaxial layer 306p described above. FIGS. 15 and 16 also show isolation structures 310, 312, 314, 316, 318, 320 (not shown in FIG. 14) at the top major surface of the semiconductor substrate 302, which are like described above.

Referring to FIGS. 14, 15, and 16, an n-type drift layer 1402 is disposed in the semiconductor substrate 302 (e.g., the epitaxial layer 306n and the semiconductor support substrate 304). The n-type drift layer 1402 in the illustrated example is a buried layer. In the cross-sectional view of FIG. 15, the n-type drift layer 1402 extends laterally from under the isolation structure 310 to under the isolation structure 312, and in the cross-sectional view of FIG. 16, the n-type drift layer 1402 extends laterally from under the isolation structure 310 to under the isolation structure 320. More details of the n-type drift layer 1402 will be described subsequently in the context of the layout of FIG. 14.

A first p-type buried layer portion 1404a and a second p-type buried layer portion 1404b (collectively, p-type buried layer 1404) are disposed in the semiconductor substrate 302 (e.g., the epitaxial layer 306n). Generally, the p-type buried layer 1404 is an inverse of the n-type drift layers 210, 202 in FIG. 2. The p-type buried layer 1404 is at a depth in the semiconductor substrate 302 that is generally the same depth of the n-type drift layer 1402. In the cross-sectional view of FIG. 15, the first p-type buried layer portion 1404a extends laterally from under the isolation structure 316 to under the isolation structure 318, and the second p-type buried layer portion 1404b is under the isolation structure 312. In the cross-sectional view of FIG. 16, the first p-type buried layer portion 1404a extends laterally from under the isolation structure 320 to under the isolation structure 318. As shown in FIG. 14, the p-type buried layer portions 1404a, 1404b form a continuous p-type buried layer 1404 that laterally encircles the level-shift transistor.

An n-type well 204 is disposed in the semiconductor substrate 302 (e.g., the epitaxial layer 306n). The n-type well 204 extends from proximate the top major surface of the semiconductor substrate 302 to and contacting (e.g., extending into) the n-type drift layer 1402. The n-type well 204 is laterally between the isolation structure 310 and the isolation structure 312 in the cross-sectional view of FIG. 15 and between the isolation structure 310 and the isolation structure 320 in the cross-sectional view of FIG. 16.

A cathode region 206 is disposed in the semiconductor substrate 302 (e.g., the epitaxial layer 306n). The cathode region 206 is in the n-type well 204 and extends from the top major surface of the semiconductor substrate 302 into the semiconductor substrate 302. The cathode region 206 is laterally between the isolation structure 310 and the isolation structure 312 in the cross-sectional view of FIG. 15 and between the isolation structure 310 and the isolation structure 320 in the cross-sectional view of FIG. 16.

A first p-type well portion 1406a and a second p-type well portion 1406b (collectively, p-type well 1406) are disposed in the semiconductor substrate 302 (e.g., the epitaxial layer 306n). The first p-type well portion 1406a and second p-type well portion 1406b each extend from proximate the top major surface of the semiconductor substrate 302 to and contacting the first p-type buried layer portion 1404a and second p-type buried layer portion 1404b, respectively. In the cross-sectional view of FIG. 15, the first p-type well portion 1406a extends laterally from under the isolation structure 316 to under the isolation structure 318, and the second p-type well portion 1406b is under the isolation structure 312. In the cross-sectional view of FIG. 16, the first p-type well portion 1406a extends laterally from under the isolation structure 320 to under the isolation structure 318. As shown in FIG. 14, the p-type well portions 1406a, 1406b form a continuous p-type well 1406 that laterally encircles the level-shift transistor.

An anode region 208 is disposed in the semiconductor substrate 302 (e.g., the epitaxial layer 306n). The anode region 208 is in the first p-type well portion 1406a and extends from the top major surface of the semiconductor substrate 302 into the semiconductor substrate 302. The anode region 208 is laterally between the isolation structure 316 and the isolation structure 318 in the cross-sectional view of FIG. 15 and between the isolation structure 320 and the isolation structure 318 in the cross-sectional view of FIG. 16.

An n-type drift region 1430 formed by the epitaxial layer 306n is at a depth at a depth in the semiconductor substrate 302 that is generally the same depth of the n-type drift layer 1402 and the p-type buried layer 1404, as shown in FIG. 16. The n-type drift region 1430 may correspond to portions of the proximal drift portion 202c and transition drift portion 202d of the n-type drift layer 202 described above.

The n-type drift layer 1402, n-type well 204, and cathode region 206 are doped with a same dopant conductivity type (e.g., n-type), and the anode region 208, p-type buried layer 1404, and p-type well 1406 are doped with a same opposite conductivity type (e.g., p-type). The diode in the junction diode area 106 includes the cathode region 206, n-type well 204, n-type drift layer 1402, anode region 208, p-type buried layer 1404, and p-type well 1406. As will be described, the level-shift transistor (e.g., an LDMOS transistor) is laterally disposed between the cathode region 206 and the anode region 208 of the diode.

In some examples, the n-type drift layer 1402 may be an n-type layer doped with an n-type dopant at a concentration in a range from about 1×10¹⁷ cm⁻³ to about 2×10²⁰ cm⁻³. In some examples, the p-type buried layer 1404 may be a p-type layer doped with a p-type dopant at a concentration in a range from about 1×10¹⁷ cm⁻³ to about 2×10²⁰ cm⁻³. In some examples, the n-type well 204 may be an n-well doped with an n-type dopant at a concentration in a range from about 1×10¹⁷ cm⁻³ to about 2×10²⁰ cm⁻³, and the p-type well 1406 may be a p-well doped with a p-type dopant at a concentration in a range from about 1×10¹⁷ cm⁻³ to about 2×10²⁰ cm⁻³. In some examples, the cathode region 206 may be n-doped with an n-type dopant at a concentration in a range from about 1×10²⁰ cm⁻³ to about 3×10²¹ cm⁻³, and the anode region 208 may be p-doped with a p-type dopant at a concentration in a range from about 1×10²⁰ cm⁻³ to about 3×10²¹ cm⁻³.

The level-shift transistor is laterally between the cathode region 206 and the anode region 208 in a transistor area 240 shown in FIG. 14, which includes the cross-section 15-15 of FIG. 15. Components of the level-shift transistor have a generally rectangular shape (e.g., including a rectangular shape with two or four rounded corners) in the layout view of FIG. 14.

Referring to FIGS. 14 and 15, an n-type buried layer 1408 is disposed in the semiconductor substrate 302 (e.g., the epitaxial layer 306n and the semiconductor support substrate 304). The n-type buried layer 1408 is at a depth in the semiconductor substrate 302 that is generally the same depth of the n-type drift layer 1402 and the p-type buried layer 1404. In the cross-sectional view of FIG. 15, the n-type buried layer 1408 extends laterally from under the isolation structure 312 to under the isolation structure 314. As shown in the layout of FIG. 14, the n-type buried layer 1408 is generally rectangular with four rounded corners.

An n-type well 1412 is disposed in the semiconductor substrate 302 (e.g., the epitaxial layer 306n). The n-type well 1412 extends from proximate the top major surface of the semiconductor substrate 302 to and contacting the n-type buried layer 1408. The n-type well 1412 extends laterally from under the isolation structure 312 to under the isolation structure 314. As shown in the layout of FIG. 14, the n-type well 1412 is generally rectangular with four rounded corners. The n-type well 1412 is generally laterally co-extensive with the n-type buried layer 1408.

A drain region 1424 is disposed in the semiconductor substrate 302 (e.g., the epitaxial layer 306n). The drain region 1424 is in the n-type well 1412 and extends from the top major surface of the semiconductor substrate 302 into the semiconductor substrate 302. The drain region 1424 is laterally between the isolation structure 312 and the isolation structure 314. As shown in the layout of FIG. 14, the drain region 1424 is generally rectangular. A width of the drain region 1424 is less than and within a width of the n-type well 1412, which widths are parallel to a channel width of the level-shift transistor (e.g., in y-directions).

A diffusion well 1418 is disposed in the semiconductor substrate 302 (e.g., the epitaxial layer 306n). The diffusion well 1418 extends from proximate the top major surface of the semiconductor substrate 302 into the semiconductor substrate 302. The diffusion well 1418 is laterally between the gate dielectric layer 322 and the isolation structure 316. As shown in the layout of FIG. 14, the diffusion well 1418 is generally rectangular. A width of the diffusion well 1418 is less than the width of the drain region 1424.

A source region 1426 and an integrated backgate region 1428 are disposed in the semiconductor substrate 302 (e.g., the epitaxial layer 306n). The source region 1426 and the integrated backgate region 1428 are in the diffusion well 1418 and extend from the top major surface of the semiconductor substrate 302 into the semiconductor substrate 302. The source region 1426 and the integrated backgate region 1428 are laterally between the gate dielectric layer 322 and the isolation structure 316. The source region 1426 is laterally proximate to or at the gate dielectric layer 322, and the integrated backgate region 1428 is laterally proximate to or at the isolation structure 316. As shown in the layout of FIG. 14, the source region 1426 and the integrated backgate region 1428 are generally rectangular. Respective widths of the source region 1426 and the integrated backgate region 1428 are less than and within the width of the diffusion well 1418, which widths are parallel to the channel width of the level-shift transistor (e.g., in y-directions).

The n-type buried layer 1408, n-type well 1412, drain region 1424, and source region 1426 are doped with a same dopant conductivity type (e.g., n-type), and the diffusion well 1418 and integrated backgate region 1428 are doped with a same opposite conductivity type (e.g., p-type). The epitaxial layer 306n may form an n-type drift region 1410, as shown in FIG. 15, laterally between the n-type buried layer 1408 and the first p-type buried layer portion 1404a that may generally correspond to the n-type drift layer 210 in FIGS. 2 and 3.

In some examples, the n-type buried layer 1408 may be an n-type layer doped with an n-type dopant at a concentration in a range from about 1×10¹⁷ cm⁻³ to about 2×10²⁰ cm⁻³. In some examples, the n-type well 1412 may be an n-well doped with an n-type dopant at a concentration in a range from about 1×10¹⁷ cm⁻³ to about 2×10²⁰ cm⁻³. In some examples, the diffusion well 1418 may be a p-well doped with a p-type dopant at a concentration in a range from about 1×10¹⁷ cm⁻³ to about 2×10²⁰ cm⁻³. In some examples, the drain region 1424 and the source region 1426 may each be n-doped with an n-type dopant at a concentration in a range from about 1×10²⁰ cm⁻³ to about 3×10²¹ cm⁻³, and the integrated backgate region 1428 may be p-doped with a p-type dopant at a concentration in a range from about 1×10²⁰ cm⁻³ to about 3×10²¹ cm⁻³.

A gate electrode 220a, a gate-coupled field plate 220b, and drain-side field plates 222a, 222b are on or over the semiconductor substrate 302. The gate electrode 220a is on and over the gate dielectric layer 322 and the isolation structure 314. The gate electrode 220a is proximate the diffusion well 1418. The gate electrode 220a is laterally between the diffusion well 1418 and the n-type well 1412, and hence, is laterally between the source region 1426 and the drain region 1424.

The gate-coupled field plate 220b is on and over the isolation structure 316. The gate-coupled field plate 220b is laterally between the diffusion well 1418 and the first p-type well portion 1406a. The drain-side field plate 222a is on and over the isolation structure 314. The drain-side field plate 222a is laterally separated from the gate electrode 220a. The drain-side field plate 222a is laterally proximate to the n-type well 1412. The drain-side field plate 222b is on and over the isolation structure 312. The drain-side field plate 222b is over the second p-type well portion 1406b and laterally between the n-type well 1412 and the n-type well 204.

In the illustrated example, as shown in FIG. 14, the gate electrode 220a and gate-coupled field plate 220b are an integrated material(s) (e.g., in a rectangular shape), and the drain-side field plates 222a, 222b are an integrate material(s) (e.g., in an ovaloid shape or generally rectangular with rounded corners). A width of the gate electrode 220a is or is parallel to the channel width of the level-shift transistor (e.g., in a y-direction). The integrated material(s) of the gate electrode 220a and gate-coupled field plate 220b laterally encircle or encompass the diffusion well 1418 and, hence, also the source region 1426 and integrated backgate region 1428. The integrated material(s) of the drain-side field plates 222a, 222b laterally encircle or encompass the n-type well 1412 and, hence, also the drain region 1424. The gate electrode 220a, gate-coupled field plate 220b, and drain-side field plates 222a, 222b are or include a conductive material, like described above.

The level-shift transistor (e.g., LDMOS transistor) includes the drain region 1424, source region 1426, n-type well 1412, diffusion well 1418, and gate electrode 220a. The channel width of the level-shift transistor is in a direction perpendicular to a direction from the drain region 1424 to the source region 1426 (e.g., in a y-direction). A channel length of the level-shift transistor is in a direction from the drain region 1424 to the source region 1426 (e.g., in an x-direction). Hence, any direction parallel to the channel width is perpendicular to the channel length, and any direction parallel to the channel length is perpendicular to the channel width.

Referring back to FIG. 14, a proximal area 242 is near the transistor area 240 (e.g., generally neighboring the transistor area 240 in a y-direction), and a transition area 244 adjoins the proximal area 242. The proximal area 242 is between the transistor area 240 and the transition area 244. As detailed subsequently, the transition area 244 is defined, for example, by a reduction in a lateral dimension of an n-type drift region formed by the epitaxial layer 306n (e.g., n-type drift region 1430) and/or in a lateral distance between the cathode region 206 and a lateral edge of the first p-type buried layer portion 1404a.

The cathode region 206 includes a first linear cathode segment 206a in the transistor area 240, a conformal cathode segment 206b at a transition from the transistor area 240 to the proximal area 242, and a second linear cathode segment 206c in the proximal area 242 and the transition area 244 and extending laterally from the transition area 244. The first linear cathode segment 206a extends linearly laterally parallel to the channel width and perpendicular to the channel length of the level-shift transistor. The conformal cathode segment 206b extends from the first linear cathode segment 206a and conforms laterally to the periphery of the level-shift transistor. The second linear cathode segment 206c extends from the conformal cathode segment 206b and linearly laterally parallel to the channel width and perpendicular to the channel length of the level-shift transistor.

The anode region 208 includes a first linear anode segment 208a in the transistor area 240 and the proximal area 242 and extending into the transition area 244, a second linear anode segment 208b in the transition area 244, and a third linear anode segment 208c extending laterally from the transition area 244. The first linear anode segment 208a extends linearly laterally parallel to the channel width and perpendicular to the channel length of the level-shift transistor. The first linear anode segment 208a, as illustrated, extends into the transition area 244 by a first lateral distance 246 from the proximal area 242. Other examples may omit such a first lateral distance 246 such that the first linear anode segment 208a does not extend into the transition area 244. The second linear anode segment 208b extends from the first linear anode segment 208a and linearly laterally non-parallel and non-perpendicular to the channel width and the channel length of the level-shift transistor. In a direction perpendicular to the channel length and parallel to the channel width (e.g., in a y-direction), the second linear anode segment 208b extends laterally a first lateral dimension 248. The first linear anode segment 208a of the anode region 208 forms a first angle 250 with the second linear anode segment 208b of the anode region 208. The first angle 250 is less than 180° and may be in a range from 90° to 170°. The third linear anode segment 208c extends from the second linear anode segment 208b and linearly laterally parallel to the channel width and perpendicular to the channel length of the level-shift transistor.

A second lateral distance 252 is between the first linear anode segment 208a of the anode region 208 and the second linear cathode segment 206c of the cathode region 206 in the proximal area 242 and the transition area 244. A lateral distance between the second linear anode segment 208b of the anode region 208 and the second linear cathode segment 206c of the cathode region 206 (e.g., illustrated by a third lateral distance 254) decreases in the transition area 244 in a direction away from the proximal area 242. A fourth lateral distance 256 is between the third linear anode segment 208c of the anode region 208 and the second linear cathode segment 206c of the cathode region 206 extending away from the transition area 244. The second lateral distance 252, third lateral distance 254, and fourth lateral distance 256 are perpendicular to the channel width and parallel to the channel length of the level-shift transistor (e.g., in x-directions).

A first lateral distance reduction is a reduction of a distance between the second linear anode segment 208b of the anode region 208 and the second linear cathode segment 206c of the cathode region 206 from proximate the level-shift transistor to distal from the level-shift transistor. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor. In some examples, a ratio of the first lateral dimension 248 to the first lateral distance reduction is in a range from 0 to 5.67. In some examples, a ratio of the fourth lateral distance 256 to the second lateral distance 252 is in a range from 1:7 to 1:1.2.

The n-type drift layer 1402 includes a first linear drift segment 1402a, a conformal drift segment 1402b, and a second linear drift segment 1402c, which generally correspond with the first linear cathode segment 206a, conformal cathode segment 206b, and second linear cathode segment 206c, respectively. The first linear drift segment 1402a is in the transistor area 240. The first linear drift segment 1402a extends linearly laterally parallel to the channel width and perpendicular to the channel length of the level-shift transistor. The conformal drift segment 1402b extends from the first linear drift segment 1402a and conforms laterally to the periphery of the p-type buried layer 1404 in the transistor area 240. The second linear drift segment 1402c extends from the conformal drift segment 1402b through the proximal area 242 and the transition area 244 and from the transition area 244. The second linear drift segment 1402c extends linearly laterally parallel to the channel width and perpendicular to the channel length of the level-shift transistor.

Generally, for each of the first linear drift segment 1402a, the conformal drift segment 1402b, and the second linear drift segment 1402c, a respective uniform distance is between the cathode region 206 and a lateral edge of the respective drift segment 1402a, 1402b, 1402c proximate to the anode region 208, where the respective uniform lateral distance is perpendicular to an instantaneous direction of lateral extension (e.g., a tangent line) of the corresponding portion of the cathode region 206. The respective lateral distances of the drift segments 1402a, 1402b, 1402c may be an equal lateral distance. The lateral distances for the first linear drift segment 1402a and the second linear drift segment 1402c are parallel to the channel length and perpendicular to the channel width of the level-shift transistor (e.g., in x-directions). The lateral distance of the conformal drift segment 1402b is non-parallel and non-perpendicular to the channel length and the channel width.

The first p-type buried layer portion 1404a includes a proximal buried layer portion 1404aa in the proximal area 242, a transition buried layer portion 1404ab in the transition area 244, and a linear buried layer portion 1404ac extending laterally from the transition area 244. The proximal buried layer portion 1404aa has a first lateral edge proximate to the second linear cathode segment 206c of the cathode region 206. A first p-n junction 260 is formed at the first lateral edge of the proximal buried layer portion 1404aa. The first lateral edge, and hence, the first p-n junction 260, extends linearly in a direction parallel to the channel width and perpendicular to the channel length of the level-shift transistor.

The transition buried layer portion 1404ab extends from the proximal buried layer portion 1404aa. The transition buried layer portion 1404ab has a third lateral dimension 262 at a second lateral edge proximate to the second linear cathode segment 206c of the cathode region 206. The third lateral dimension 262 is in a direction parallel to the channel width and perpendicular to the channel length of the level-shift transistor. A second p-n junction 264 is formed at the second lateral edge of the transition buried layer portion 1404ab. The second lateral edge, and hence, the second p-n junction 264, extends linearly in a direction non-parallel and non-perpendicular to the channel width and the channel length of the level-shift transistor. The second lateral edge (e.g., at the second p-n junction 264) of the transition buried layer portion 1404ab forms a second angle 266 with the first lateral edge (e.g., at the first p-n junction 260) of the proximal buried layer portion 1404aa. The second angle 266 is formed laterally exterior to the first p-type buried layer portion 1404a. The second angle 266 is less than 180° and may be in a range from 90° to 170°. In some examples, the first angle 250 formed by the anode region 208 is less than the second angle 266 formed by the first p-type buried layer portion 1404a.

The linear buried layer portion 1404ac extends from the transition buried layer portion 1404ab and linearly laterally parallel to the channel width and perpendicular to the channel length of the level-shift transistor. The linear buried layer portion 1404ac has a third lateral edge, at which a third p-n junction 268 is formed, proximate to the second linear cathode segment 206c of the cathode region 206. The third lateral edge, and hence, the third p-n junction 268, extends linearly in a direction parallel to the channel width and perpendicular to the channel length of the level-shift transistor.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the second lateral edge (e.g., at the second p-n junction 264) and the second linear cathode segment 206c of the cathode region 206 decreases (e.g., relative to the fifth lateral distance 272) in the transition area 244 in a direction away from the proximal area 242. A seventh lateral distance 276 is between the third lateral edge (e.g., at the third p-n junction 268) and the second linear cathode segment 206c of the cathode region 206. The fifth lateral distance 272, sixth lateral distance 274, and seventh lateral distance 276 are perpendicular to the channel width and parallel to the channel length of the level-shift transistor (e.g., in x-directions). As illustrated, a distance from a lateral edge of the transition buried layer portion 1404ab to the second linear cathode segment 206c of the cathode region 206 reduces resulting in a reduction of a lateral distance from the fifth lateral distance 272 in the transition area 244 proximate to the level-shift transistor to the seventh lateral distance 276 in the transition area 244 distal from the level-shift transistor.

A second lateral distance reduction is a reduction of a distance between the second lateral edge (e.g., at the second p-n junction 264) and the second linear cathode segment 206c of the cathode region 206 from proximate the level-shift transistor to distal from the level-shift transistor. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the first linear anode segment 208a of the anode region 208 and the first lateral edge (e.g., at the first p-n junction 260) of the proximal buried layer portion 1404aa of the first p-type buried layer portion 1404a in the proximal area 242. A lateral distance between the second linear anode segment 208b of the anode region 208 and the second lateral edge (e.g., at the second p-n junction 264) of the transition buried layer portion 1404ab of the first p-type buried layer portion 1404a (e.g., illustrated by a ninth lateral distance 284) decreases in the transition area 244 in a direction away from the proximal area 242. A tenth lateral distance 286 is between the third linear anode segment 208c of the anode region 208 and the third lateral edge (e.g., at the third p-n junction 268) of the linear buried layer portion 1404ac of the first p-type buried layer portion 1404a extending away from the transition area 244. The eighth lateral distance 282, ninth lateral distance 284, and tenth lateral distance 286 are perpendicular to the channel width and parallel to the channel length of the level-shift transistor (e.g., in x-directions).

A third lateral distance reduction is a reduction of a distance between the first linear anode segment 208a and/or second linear anode segment 208b of the anode region 208 and the second lateral edge (e.g., at the second p-n junction 264) from proximate the level-shift transistor to distal from the level-shift transistor. The third lateral distance reduction is the difference between the eighth lateral distance 282 and the tenth lateral distance 286. The third lateral distance reduction is in a direction (e.g., in an x-direction) parallel to the channel length and perpendicular to the channel width of the level-shift transistor. In some examples, a ratio of the tenth lateral distance 286 to the eighth lateral distance 282 is in a range from 1:7 to 1:1.2.

Due to the extension of the first linear anode segment 208a into the transition area 244 by the first lateral distance 246 in some examples, the lateral distance between the anode region 208 and the second linear cathode segment 206c of the cathode region 206 may initially stay the same from the boundary between the proximal area 242 and the transition area 244 before decreasing in the transition area 244 in a direction away from the proximal area 242. Also, the lateral distance between the anode region 208 and the second lateral edge (e.g., at the second p-n junction 264) of the transition buried layer portion 1404ab of the first p-type buried layer portion 1404a may initially increase from the boundary between the proximal area 242 and the transition area 244 before decreasing in the transition area 244 in a direction away from the proximal area 242.

As described, a lateral distance (e.g., the sixth lateral distance 274) between the cathode region 206 and a second lateral edge (e.g., at the second p-n junction 264) of the first p-type buried layer portion 1404a proximate the cathode region 206 decreases from proximate the level-shift transistor to distal from the level-shift transistor. The lateral distance is parallel to the channel length and perpendicular to the channel width of the level-shift transistor. The cathode region 206 (e.g., the second linear cathode segment 206c) extends in a direction perpendicular to the channel length and parallel to the channel width corresponding to where (e.g., in the transition area 244) the lateral distance (e.g., the sixth lateral distance 274) decreases from proximate the level-shift transistor to distal from the level-shift transistor. The anode region 208 (e.g., the second linear anode segment 208b) extends laterally in a direction non-parallel and/or non-perpendicular to the channel width and/or the channel length corresponding to where (e.g., in the transition area 244) the lateral distance (e.g., the sixth lateral distance 274) decreases from proximate the level-shift transistor to distal from the level-shift transistor.

A lateral distance (e.g., the third lateral distance 254) between the anode region 208 and the cathode region 206 decreases from proximate the level-shift transistor to distal from the level-shift transistor corresponding, at least in part, to where (e.g., in the transition area 244) the lateral distance (e.g., the sixth lateral distance 274) decreases from proximate the level-shift transistor to distal from the level-shift transistor. A lateral distance (e.g., the ninth lateral distance 284) between the anode region 208 and a second lateral edge (e.g., at the second p-n junction 264) of the first p-type buried layer portion 1404a proximate the cathode region 206 decreases from proximate the level-shift transistor to distal from the level-shift transistor corresponding, at least in part, to where (e.g., in the transition area 244) the lateral distance (e.g., the sixth lateral distance 274) decreases from proximate the level-shift transistor to distal from the level-shift transistor.

Similarly, a lateral distance (e.g., the third lateral distance 254) between the anode region 208 and the cathode region 206 decreases as the anode region 208 extends laterally non-parallel and non-perpendicular to the channel width and/or channel length (e.g., in the transition area 244). The cathode region 206 extends in a direction parallel to the channel width and perpendicular to the channel length corresponding to where (e.g., in the transition area 244) the anode region 208 extends laterally non-parallel and non-perpendicular to the channel width and/or channel length distally away from the level-shift transistor.

A fifth lateral dimension 1442 is between the first p-type buried layer portion 1404a and the second p-type buried layer portion 1404b (corresponding to the n-type drift region 1410 of the epitaxial layer 306n and the n-type buried layer 1408). The fifth lateral dimension 1442 is parallel to the channel length and perpendicular to the channel width of the level-shift transistor (e.g., in an x-direction). The proximal buried layer portion 1404aa of the first p-type buried layer portion 1404a laterally overlaps in directions parallel to the channel width and perpendicular to the channel length (e.g., in y-directions) the n-type drift region 1410 in the epitaxial layer 306n of the level-shift transistor by an overlapping lateral dimension 1444. The n-type drift region 1410 in the epitaxial layer 306n of the level-shift transistor does not laterally overlap in directions parallel to the channel width and perpendicular to the channel length (e.g., in y-directions) the proximal buried layer portion 1404aa of the first p-type buried layer portion 1404a by a non-overlapping lateral dimension 1446. The overlapping lateral dimension 1444 and the non-overlapping lateral dimension 1446 are in directions parallel to the channel length and perpendicular to the channel width (e.g., in x-directions). In some examples, the overlapping lateral dimension 1444 is equal to or less than 66% of the fifth lateral dimension 1442 (e.g., for a lower voltage rating), which percentage may be decreased for a higher voltage rating. In some examples, the non-overlapping lateral dimension 1446 is equal to or greater than 33% of the fifth lateral dimension 1442 (e.g., for a lower voltage rating), which percentage may be increased for a higher voltage rating.

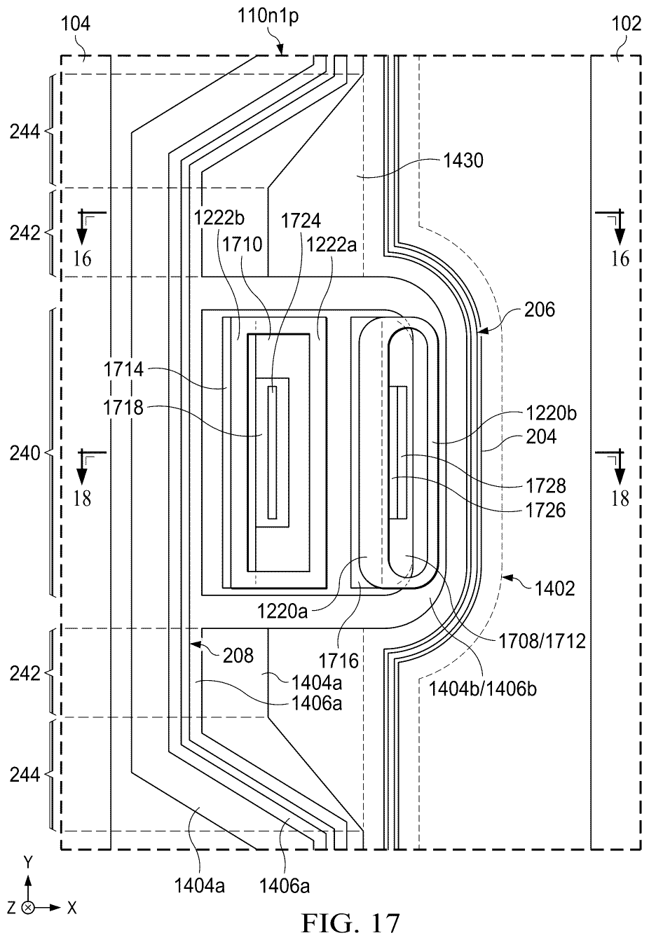

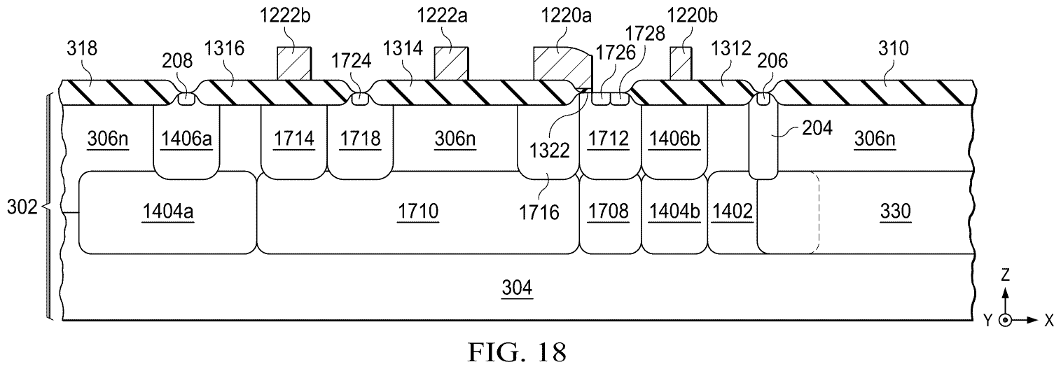

FIG. 17 is a layout of an inset 110n1p as an example of the inset 110 of FIG. 1 according to some examples. FIG. 17 shows a cross-section 18-18 and a cross-section 16-16. FIG. 18 shows a cross-sectional view of the cross-section 18-18 of FIG. 17, and FIG. 16 shows the cross-sectional view of the cross-section 16-16 of FIG. 17. In FIGS. 17, 18, and 16, the level-shift transistor is a p-type LDMOS transistor in an n-type epitaxial layer (or more generally, semiconductor substrate), as will be detailed subsequently.

The layout of FIG. 17 is in and/or on a semiconductor substrate 302, which is shown in FIGS. 16 and 18. The semiconductor substrate 302, in the illustrated examples, includes a semiconductor support substrate 304 and an epitaxial layer 306n. The semiconductor substrate 302, including the epitaxial layer 306n, may be as described above. FIG. 18 also shows isolation structures 310, 1312, 1314, 1316, 318 at the top major surface of the semiconductor substrate 302, which like described above. A gate dielectric layer 1322 is at the top the top major surface of the semiconductor substrate 302, as described above.

Referring to FIGS. 17, 18, and 16, the diode includes the cathode region 206, n-type well 204, n-type drift layer 1402, anode region 208, p-type well 1406, and p-type buried layer 1404 as described above with respect to FIGS. 14, 15, and 16. Although not illustrated in FIG. 17, the n-type drift layer 1402 includes the first linear drift segment 1402a, conformal drift segment 1402b, and second linear drift segment 1402c. The cathode region 206 includes the first linear cathode segment 206a, conformal cathode segment 206b, and second linear cathode segment 206c. The p-type buried layer 1404 includes the first p-type buried layer portion 1404a and second p-type buried layer portion 1404b. The first p-type buried layer portion 1404a includes the proximal buried layer portion 1404aa, transition buried layer portion 1404ab, and linear buried layer portion 1404ac. The anode region 208 includes the first linear anode segment 208a, second linear anode segment 208b, third linear anode segment 208c. The relationships between the cathode region 206, n-type well 204, n-type drift layer 1402, anode region 208, p-type well 1406, and/or p-type buried layer 1404 are as described above, although not illustrated in FIG. 17.

The level-shift transistor is laterally between the cathode region 206 and the anode region 208 in a transistor area 240 shown in FIG. 17, which includes the cross-section 18-18 of FIG. 18. Components of the level-shift transistor have a generally rectangular shape (e.g., including a rectangular shape with two or four rounded corners) in the layout view of FIG. 17.

Referring to FIGS. 17 and 18, an n-type buried layer 1708 is disposed in the semiconductor substrate 302 (e.g., the epitaxial layer 306n and the semiconductor support substrate 304). The n-type buried layer 1708 is at a depth in the semiconductor substrate 302 that is generally the same depth of the n-type drift layer 1402 and the p-type buried layer 1404. The n-type buried layer 1708 extends laterally between the isolation structure 1312 and the isolation structure 1314. The second p-type buried layer portion 1404b is laterally between the n-type drift layer 1402 and the n-type buried layer 1708. The n-type buried layer 1708, as illustrated in FIG. 17, is generally rectangular with rounded corners proximate the second p-type buried layer portion 1404b.

A p-type drift layer 1710 is disposed in the semiconductor substrate 302 (e.g., the epitaxial layer 306n and the semiconductor support substrate 304). The p-type drift layer 1710 in the illustrated example is a buried layer. The p-type drift layer 1710 is at a depth in the semiconductor substrate 302 that is generally the same depth of the n-type buried layer 1708, n-type drift layer 1402, and p-type buried layer 1404. The n-type buried layer 1708 is laterally between the p-type drift layer 1710 and the second p-type buried layer portion 1404b. The p-type drift layer 1710 extends laterally from under the gate dielectric layer 1322 to under the isolation structure 1316, including under the isolation structure 1314. The p-type drift layer 1710, as illustrated in FIG. 17, is generally rectangular.

N-type wells 1712, 1714 are disposed in the semiconductor substrate 302 (e.g., the epitaxial layer 306n). The n-type well 1712 extends from proximate the top major surface of the semiconductor substrate 302 to and contacting the n-type buried layer 1708. The n-type well 1714 extends from proximate the top major surface of the semiconductor substrate 302 to and contacting the p-type drift layer 1710. The n-type well 1712 extends from under the isolation structure 1312 to under the gate dielectric layer 1322. The n-type well 1712 is laterally co-extensive with the n-type buried layer 1708. The n-type well 1714 is under the isolation structure 1316. As shown in the layout of FIG. 17, the n-type well 1712 is generally rectangular with four rounded corners, and the n-type well 1714 is generally rectangular. Respective widths of the n-type wells 1712, 1714 are equal to and co-extensive with respective widths of the n-type buried layer 1708 and p-type drift layer 1710, which widths are also equal and are parallel to a channel width (indicated subsequently) of the level-shift transistor (e.g., in y-directions).

P-type wells 1716, 1718 are disposed in the semiconductor substrate 302 (e.g., the epitaxial layer 306n). The p-type wells 1716, 1718 each extend from proximate the top major surface of the semiconductor substrate 302 to and contacting the p-type drift layer 1710. The p-type wells 1716, 1718 are laterally separated and are laterally between the n-type wells 1712, 1714. The p-type well 1716 is under the gate dielectric layer 1322 and the isolation structure 1314. The p-type well 1718 is laterally between the isolation structure 1314 and the isolation structure 1316. As shown in the layout of FIG. 17, the p-type wells 1716, 1718 are generally rectangular. Respective widths of the p-type wells 1716, 1718 are less than and within the width of the p-type drift layer 1710, which widths are parallel to the channel width of the level-shift transistor (e.g., in y-directions).

A drain region 1724 is disposed in the semiconductor substrate 302 (e.g., the epitaxial layer 306n). The drain region 1724 is in the p-type well 1718 and extends from the top major surface of the semiconductor substrate 302 into the semiconductor substrate 302. The drain region 1724 is laterally between the isolation structure 1314 and the isolation structure 1316. As shown in the layout of FIG. 17, the drain region 1724 is generally rectangular. A width of the drain region 1724 is less than and within the width of the p-type well 1718, which widths are parallel to the channel width of the level-shift transistor (e.g., in y-directions).

A source region 1726 and an integrated backgate region 1728 are disposed in the semiconductor substrate 302 (e.g., the epitaxial layer 306n). The source region 1726 and the integrated backgate region 1728 are in the n-type well 1712 and extend from the top major surface of the semiconductor substrate 302 into the semiconductor substrate 302. The source region 1726 and the integrated backgate region 1728 are laterally between the gate dielectric layer 1322 and the isolation structure 1312. The source region 1726 is laterally proximate to or at the gate dielectric layer 1322, and the integrated backgate region 1728 is laterally proximate to or at the isolation structure 1312. As shown in the layout of FIG. 17, the source region 1726 and the integrated backgate region 1728 are generally rectangular. Respective widths of the source region 1726 and the integrated backgate region 1728 are less than and within the width of the n-type well 1712, which widths are parallel to the channel width of the level-shift transistor (e.g., in y-directions).

The n-type buried layer 1708, n-type wells 1712, 1714, and integrated backgate region 1728 are doped with a same dopant conductivity type (e.g., n-type), and the p-type drift layer 1710, p-type wells 1716, 1718, drain region 1724, and source region 1726 are doped with a same opposite conductivity type (e.g., p-type).

In some examples, the n-type buried layer 1708 may be an n-type layer doped with an n-type dopant at a concentration in a range from about 1×10¹⁷ cm⁻³ to about 2×10²⁰ cm⁻³, and the p-type drift layer 1710 may be a p-type layer doped with a p-type dopant at a concentration in a range from about 1×10¹⁷ cm⁻³ to about 2×10²⁰ cm⁻³. In some examples, the n-type wells 1712, 1714 may each be an n-well doped with an n-type dopant at a concentration in a range from about 1×10¹⁷ cm⁻³ to about 2×10²⁰ cm⁻³, and the p-type wells 1716, 1718 may each be a p-well doped with a p-type dopant at a concentration in a range from about 1×10¹⁷ cm⁻³ to about 2×10²⁰ cm⁻³. In some examples, the drain region 1724 and the source region 1726 may each be p-doped with a p-type dopant at a concentration in a range from about 1×10²⁰ cm⁻³ to about 3×10²¹ cm⁻³, and the integrated backgate region 1728 may be n-doped with an n-type dopant at a concentration in a range from about 1×10²⁰ cm⁻³ to about 3×10²¹ cm⁻³.

A gate electrode 1220a, a gate-coupled field plate 1220b, and drain-side field plates 1222a, 1222b are on or over the semiconductor substrate 302. The gate electrode 1220a, gate-coupled field plate 1220b, and drain-side field plates 1222a, 1222b are like described above. The gate electrode 1220a is on and over the gate dielectric layer 1322 and the isolation structure 1314. The gate electrode 1220a is over, at least partially, the n-type well 1712 and the p-type well 1716. The gate electrode 1220a is laterally between the source region 1726 and the drain region 1724.

The gate-coupled field plate 1220b is on and over the isolation structure 1312. The gate-coupled field plate 1220b is over the second p-type well portion 1406b. The drain-side field plate 1222a is on and over the isolation structure 1314. The drain-side field plate 1222a is laterally separated from the gate electrode 1220a. The drain-side field plate 1222b is on and over the isolation structure 1316 and over the n-type well 1714.

In the illustrated example, as shown in FIG. 17, the gate electrode 1220a and gate-coupled field plate 1220b are an integrated material(s) (e.g., in an ovaloid shape or generally rectangular with rounded corners), and the drain-side field plates 1222a, 1222b are an integrate material(s) (e.g., in a rectangular shape). A width of the gate electrode 1220a is or is parallel to the channel width of the level-shift transistor (e.g., in a y-direction). The width of the gate electrode 1220a is equal to the width of the p-type drift layer 1710. The integrated material(s) of the gate electrode 1220a and gate-coupled field plate 1220b laterally encircle or encompass the n-type well 1712 and, hence, also the source region 1726 and integrated backgate region 1728. The integrated material(s) of the drain-side field plates 1222a, 1222b laterally encircle or encompass the p-type well 1718 and, hence, also the drain region 1724.

The level-shift transistor (e.g., LDMOS transistor) includes the drain region 1724, source region 1726, n-type buried layer 1708, p-type drift layer 1710, n-type wells 1712, 1714, p-type wells 1716, 1718, and gate electrode 1220a. The channel width of the level-shift transistor is in a direction perpendicular to a direction from the drain region 1724 to the source region 1726 (e.g., in a y-direction). A channel length of the level-shift transistor is in a direction from the drain region 1724 to the source region 1726 (e.g., in an x-direction). Hence, any direction parallel to the channel width is perpendicular to the channel length, and any direction parallel to the channel length is perpendicular to the channel width.

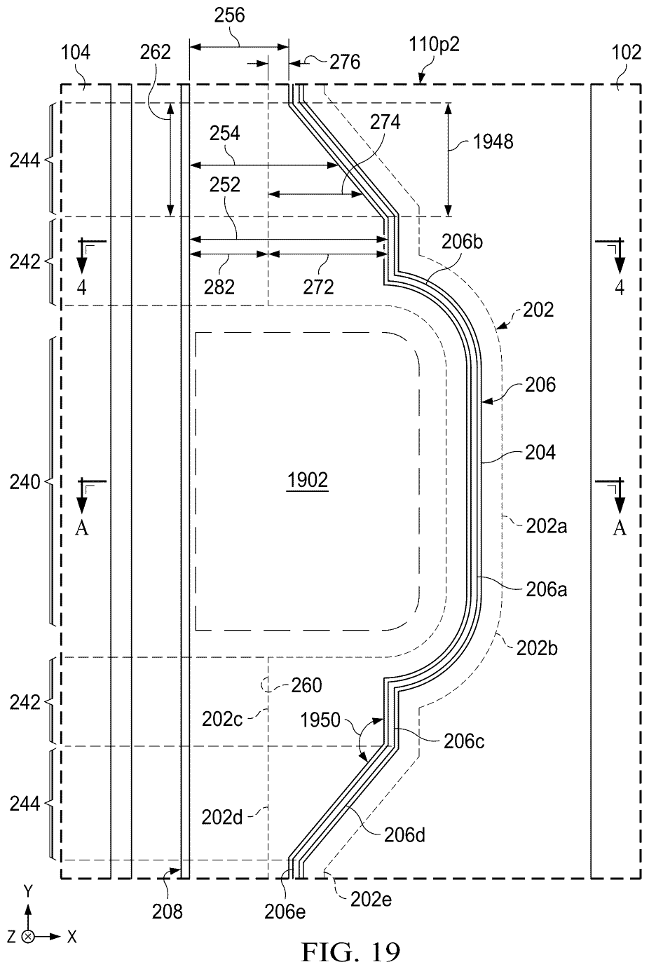

FIG. 19 is a layout of an inset 110p2 as an example of the inset 110 of FIG. 1 according to some examples. FIG. 19 shows a cross-section A-A and a cross-section 4-4. The cross-section A-A of FIG. 19 may be the cross sectional view of FIG. 3 (e.g., with an n-type LDMOS) or the cross sectional view of FIG. 13 (e.g., with a p-type LDMOS), and FIG. 4 shows a cross-sectional view of the cross-section 4-4 of FIG. 19. In FIG. 19, the level-shift transistor 1902 may be an n-type LDMOS transistor or a p-type LDMOS in a p-type epitaxial layer (or more generally, semiconductor substrate).

An n-type drift layer 202 is disposed in the semiconductor substrate 302 (e.g., the epitaxial layer 306p and semiconductor support substrate 304). The n-type drift layer 202 in the illustrated example is a buried layer. An n-type well 204 is disposed in the semiconductor substrate 302 (e.g., the epitaxial layer 306p). The n-type well 204 extends from proximate the top major surface of the semiconductor substrate 302 to and contacting (e.g., extending into) the n-type drift layer 202, as described previously. A cathode region 206 is disposed in the semiconductor substrate 302 (e.g., the epitaxial layer 306p). The cathode region 206 is in the n-type well 204 and extends from the top major surface of the semiconductor substrate 302 into the semiconductor substrate 302, as described previously. An anode region 208 is disposed in the semiconductor substrate 302 (e.g., the epitaxial layer 306p). The anode region 208 extends from the top major surface of the semiconductor substrate 302 into the semiconductor substrate 302, as described previously.

The level-shift transistor 1902 (e.g., an LDMOS transistor) is laterally disposed between the cathode region 206 and the anode region 208 of the diode. The channel width of the level-shift transistor 1902 is in a direction perpendicular to a direction from the drain region 224, 1224 to the source region 226, 1226 (e.g., in a y-direction). A channel length of the level-shift transistor 1902 is in a direction from the drain region 224, 1224 to the source region 226, 1226 (e.g., in an x-direction). Hence, any direction parallel to the channel width is perpendicular to the channel length, and any direction parallel to the channel length is perpendicular to the channel width.

A proximal area 242 is near the transistor area 240 (e.g., generally neighboring the transistor area 240 in a y-direction), and a transition area 244 adjoins the proximal area 242. The proximal area 242 is between the transistor area 240 and the transition area 244. As detailed subsequently, the transition area 244 is defined by a reduction in a lateral distance between the cathode region 206 and a lateral edge of the n-type drift layer 202.

The cathode region 206 includes a first linear cathode segment 206a in the transistor area 240, a conformal cathode segment 206b at a transition from the transistor area 240 to the proximal area 242, a second linear cathode segment 206c in the proximal area 242, a third linear cathode segment 206d in the transition area 244, and a fourth linear cathode segment 206e extending laterally from the transition area 244. The first linear cathode segment 206a extends linearly laterally parallel to the channel width and perpendicular to the channel length of the level-shift transistor 1902. The conformal cathode segment 206b extends from the first linear cathode segment 206a and conforms laterally to the periphery of the level-shift transistor 1902. The second linear cathode segment 206c extends from the conformal cathode segment 206b and linearly laterally parallel to the channel width and perpendicular to the channel length of the level-shift transistor 1902.

The third linear cathode segment 206d extends from the second linear cathode segment 206c and linearly laterally non-parallel to the channel width and non-perpendicular to the channel length of the level-shift transistor 1902. In a direction perpendicular to the channel length and parallel to the channel width (e.g., in a y-direction), the third linear cathode segment 206d extends laterally a first lateral dimension 1948. An angle 1950 is formed by respective lateral sides of the second linear cathode segment 206c and the third linear cathode segment 206d proximate to the anode region 208. The angle 1950 is less than 180° and may be in a range from 90° to 170°. The fourth linear cathode segment 206e extends from the third linear cathode segment 206d and linearly laterally parallel to the channel width and perpendicular to the channel length of the level-shift transistor 1902.

The anode region 208 extends linearly laterally parallel to the channel width and perpendicular to the channel length of the level-shift transistor 1902 (e.g., in a y-direction) through the transistor area 240, the proximal area 242, and the transition area 244 and from the transition area 244.

A second lateral distance 252 is between the anode region 208 and the second linear cathode segment 206c of the cathode region 206 in the proximal area 242 and the transition area 244. A lateral distance between the anode region 208 and the third linear cathode segment 206d of the cathode region 206 (e.g., illustrated by a third lateral distance 254) decreases in the transition area 244 in a direction away from the proximal area 242. A fourth lateral distance 256 is between the anode region 208 and the fourth linear cathode segment 206e of the cathode region 206 extending away from the transition area 244. The second lateral distance 252, third lateral distance 254, and fourth lateral distance 256 are perpendicular to the channel width and parallel to the channel length of the level-shift transistor 1902 (e.g., in x-directions).

A first lateral distance reduction is a reduction of a distance between the anode region 208 and the third linear cathode segment 206d of the cathode region 206 from proximate the level-shift transistor 1902 to distal from the level-shift transistor 1902. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor 1902. In some examples, a ratio of the first lateral dimension 1948 to the first lateral distance reduction is in a range from 0 to 5.67. In some examples, a ratio of the fourth lateral distance 256 to the second lateral distance 252 is in a range from 1:7 to 1:1.2.

The n-type drift layer 202 includes a first linear drift portion 202a in the transistor area 240, a conformal drift portion 202b at a transition from the transistor area 240 to the proximal area 242, a proximal drift portion 202c in the proximal area 242, a transition drift portion 202d in the transition area 244, and a second linear drift portion 202e extending laterally from the transition area 244. The first linear drift portion 202a extends linearly laterally parallel to the channel width and perpendicular to the channel length of the level-shift transistor 1902. The conformal drift portion 202b extends from the first linear drift portion 202a and conforms laterally to the periphery of the level-shift transistor 1902.

The proximal drift portion 202c extends from the conformal drift portion 202b. The proximal drift portion 202c has a first lateral edge, at which a first p-n junction 260 is formed, proximate to the anode region 208. The first lateral edge, and hence, the first p-n junction 260, extends linearly in a direction parallel to the channel width and perpendicular to the channel length of the level-shift transistor 1902. The first p-n junction 260 is formed at the first lateral edge of the n-type drift layer 202 in the epitaxial layer 306p.

The transition drift portion 202d extends from the proximal drift portion 202c. The transition drift portion 202d has a third lateral dimension 262 in a direction parallel to the channel width and perpendicular to the channel length of the level-shift transistor 1902. The transition drift portion 202d continues the first lateral edge proximate to the anode region 208. In other examples, the transition drift portion 202d may have another lateral edge that forms an angle less than 180° with the first lateral edge (e.g., the other lateral edge may extend linearly in a direction non-parallel and non-perpendicular to the channel width and the channel length of the level-shift transistor 1902). The second linear drift portion 202e extends from the transition drift portion 202d and linearly laterally parallel to the channel width and perpendicular to the channel length of the level-shift transistor 1902. The second linear drift portion 202e continues the first lateral edge proximate to the anode region 208.

Generally, for each of the first linear drift portion 202a, the conformal drift portion 202b, and the second linear drift portion 202e, a respective uniform distance is between the cathode region 206 and a lateral edge of the respective drift portion 202a, 202b, 202e proximate to the anode region 208, where the respective uniform lateral distance is perpendicular to an instantaneous direction of lateral extension (e.g., a tangent line) of the corresponding portion of the cathode region 206. The respective lateral distances of the drift portions 202a, 202b, 202e may be an equal lateral distance. The lateral distances for the first linear drift portion 202a and the second linear drift portion 202e are parallel to the channel length and perpendicular to the channel width of the level-shift transistor 1902 (e.g., in x-directions). The lateral distance of the conformal drift portion 202b is non-parallel and non-perpendicular to the channel length and the channel width.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the first lateral edge and the third linear cathode segment 206d of the cathode region 206 decreases (e.g., relative to the fifth lateral distance 272) in the transition area 244 in a direction away from the proximal area 242. A seventh lateral distance 276 is between the first lateral edge and the fourth linear cathode segment 206e of the cathode region 206. The fifth lateral distance 272, sixth lateral distance 274, and seventh lateral distance 276 are perpendicular to the channel width and parallel to the channel length of the level-shift transistor 1902 (e.g., in x-directions). As illustrated, the transition drift portion 202d has a lateral dimension that reduces resulting in a reduction of a lateral distance from the fifth lateral distance 272 in the transition area 244 proximate to the level-shift transistor 1902 to the seventh lateral distance 276 in the transition area 244 distal from the level-shift transistor 1902.

A second lateral distance reduction is a reduction of a distance between the first lateral edge (e.g., at the first p-n junction 260) and the third linear cathode segment 206d of the cathode region 206 from proximate the level-shift transistor 1902 to distal from the level-shift transistor 1902. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor 1902. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the anode region 208 and the first lateral edge (e.g., at the first p-n junction 260) of the proximal drift portion 202c and the transition drift portion 202d of the n-type drift layer 202 in the proximal area 242 and the transition area 244. In the illustrated example, the eighth lateral distance 282 is uniform throughout the proximal area 242 and the transition area 244. In other examples, a lateral distance between the anode region 208 and another lateral edge of the transition drift portion 202d of the n-type drift layer 202 may decrease in the transition area 244 in a direction away from the proximal area 242. The eighth lateral distance 282 is perpendicular to the channel width and parallel to the channel length of the level-shift transistor 1902 (e.g., in x-directions).

Although the level-shift transistor 1902 is not specifically illustrated, the level-shift transistor 1902 may include an n-type drift layer (e.g., the n-type drift layer 210, 1210). The n-type drift layer may have a lateral dimension parallel to the channel length and perpendicular to the channel width of the level-shift transistor 1902 (e.g., in an x-direction). The proximal drift portion 202c of the n-type drift layer 202 may laterally overlap in directions parallel to the channel width and perpendicular to the channel length (e.g., in y-directions) the n-type drift layer of the level-shift transistor 1902 by an overlapping lateral dimension, as described above. The n-type drift layer of the level-shift transistor 1902 may not laterally overlap in directions parallel to the channel width and perpendicular to the channel length (e.g., in y-directions) the proximal drift portion 202c of the n-type drift layer 202 by a non-overlapping lateral dimension, as described above.

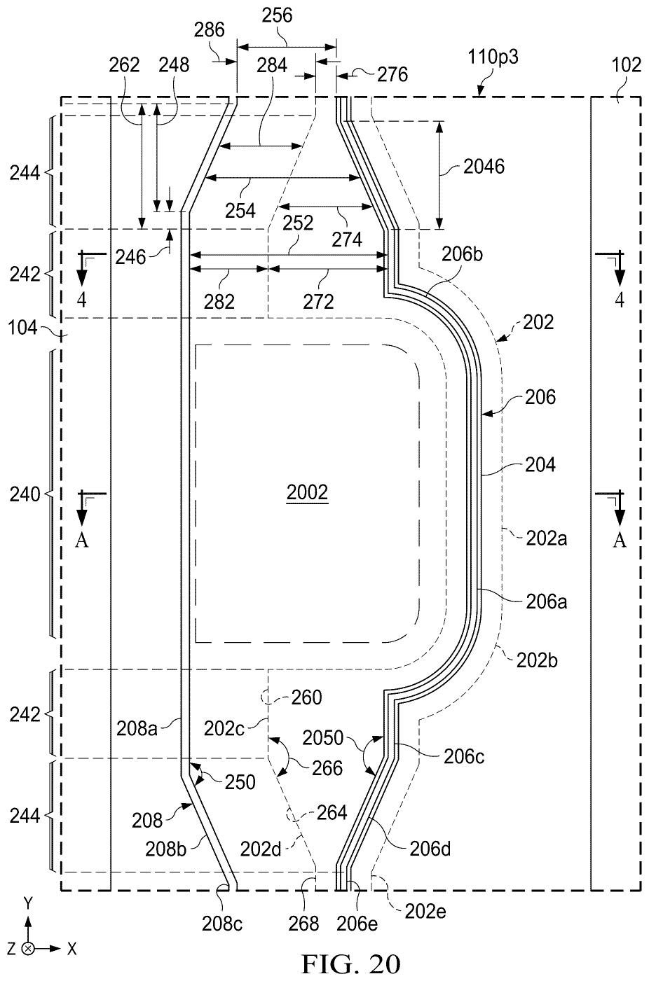

FIG. 20 is a layout of an inset 110p3 as an example of the inset 110 of FIG. 1 according to some examples. FIG. 20 shows a cross-section A-A and a cross-section 4-4. The cross-section A-A of FIG. 20 may be the cross sectional view of FIG. 3 (e.g., with an n-type LDMOS) or the cross sectional view of FIG. 13 (e.g., with a p-type LDMOS), and FIG. 4 shows a cross-sectional view of the cross-section 4-4 of FIG. 20. In FIG. 20, the level-shift transistor 2002 may be an n-type LDMOS transistor or a p-type LDMOS in a p-type epitaxial layer (or more generally, semiconductor substrate).

An n-type drift layer 202 is disposed in the semiconductor substrate 302 (e.g., the epitaxial layer 306p and semiconductor support substrate 304). The n-type drift layer 202 in the illustrated example is a buried layer. An n-type well 204 is disposed in the semiconductor substrate 302 (e.g., the epitaxial layer 306p). The n-type well 204 extends from proximate the top major surface of the semiconductor substrate 302 to and contacting (e.g., extending into) the n-type drift layer 202, as described previously. A cathode region 206 is disposed in the semiconductor substrate 302 (e.g., the epitaxial layer 306p). The cathode region 206 is in the n-type well 204 and extends from the top major surface of the semiconductor substrate 302 into the semiconductor substrate 302, as described previously. An anode region 208 is disposed in the semiconductor substrate 302 (e.g., the epitaxial layer 306p). The anode region 208 extends from the top major surface of the semiconductor substrate 302 into the semiconductor substrate 302, as described previously.

The level-shift transistor 2002 (e.g., an LDMOS transistor) is laterally disposed between the cathode region 206 and the anode region 208 of the diode. The channel width of the level-shift transistor 2002 is in a direction perpendicular to a direction from the drain region 224, 1224 to the source region 226, 1226 (e.g., in a y-direction). A channel length of the level-shift transistor 2002 is in a direction from the drain region 224, 1224 to the source region 226, 1226 (e.g., in an x-direction). Hence, any direction parallel to the channel width is perpendicular to the channel length, and any direction parallel to the channel length is perpendicular to the channel width.

A proximal area 242 is near the transistor area 240 (e.g., generally neighboring the transistor area 240 in a y-direction), and a transition area 244 adjoins the proximal area 242. The proximal area 242 is between the transistor area 240 and the transition area 244. As detailed subsequently, the transition area 244 is defined by a reduction in a lateral dimension of the n-type drift layer 202 and/or in a lateral distance between the cathode region 206 and a lateral edge of the n-type drift layer 202.

The cathode region 206 includes a first linear cathode segment 206a in the transistor area 240, a conformal cathode segment 206b at a transition from the transistor area 240 to the proximal area 242, a second linear cathode segment 206c in the proximal area 242, a third linear cathode segment 206d in the transition area 244, and a fourth linear cathode segment 206e extending laterally from the transition area 244. The first linear cathode segment 206a extends linearly laterally parallel to the channel width and perpendicular to the channel length of the level-shift transistor 2002. The conformal cathode segment 206b extends from the first linear cathode segment 206a and conforms laterally to the periphery of the level-shift transistor 2002. The second linear cathode segment 206c extends from the conformal cathode segment 206b and linearly laterally parallel to the channel width and perpendicular to the channel length of the level-shift transistor 2002.

The third linear cathode segment 206d extends from the second linear cathode segment 206c and linearly laterally non-parallel to the channel width and non-perpendicular to the channel length of the level-shift transistor 2002. In a direction perpendicular to the channel length and parallel to the channel width (e.g., in a y-direction), the third linear cathode segment 206d extends laterally a first lateral dimension 2046. An angle 2050 is formed by respective lateral sides of the second linear cathode segment 206c and the third linear cathode segment 206d proximate to the anode region 208. The angle 2050 is less than 180° and may be in a range from 90° to 170°. The fourth linear cathode segment 206e extends from the third linear cathode segment 206d and linearly laterally parallel to the channel width and perpendicular to the channel length of the level-shift transistor 2002.

The anode region 208 includes a first linear anode segment 208a in the transistor area 240 and the proximal area 242 and extending into the transition area 244, a second linear anode segment 208b in the transition area 244, and a third linear anode segment 208c extending laterally from the transition area 244. The first linear anode segment 208a extends linearly laterally parallel to the channel width and perpendicular to the channel length of the level-shift transistor 2002. The first linear anode segment 208a, as illustrated, extends into the transition area 244 by a first lateral distance 246 from the proximal area 242. Other examples may omit such a first lateral distance 246 such that the first linear anode segment 208a does not extend into the transition area 244. The second linear anode segment 208b extends from the first linear anode segment 208a and linearly laterally non-parallel and non-perpendicular to the channel width and the channel length of the level-shift transistor 2002. In a direction perpendicular to the channel length and parallel to the channel width (e.g., in a y-direction), the second linear anode segment 208b extends laterally a first lateral dimension 248. The first linear anode segment 208a of the anode region 208 forms a first angle 250 with the second linear anode segment 208b of the anode region 208. The first angle 250 is less than 180° and may be in a range from 90° to 170°. The third linear anode segment 208c extends from the second linear anode segment 208b and linearly laterally parallel to the channel width and perpendicular to the channel length of the level-shift transistor 2002.

A second lateral distance 252 is between the first linear anode segment 208a of the anode region 208 and the second linear cathode segment 206c of the cathode region 206 in the proximal area 242 and the transition area 244. A lateral distance between the second linear anode segment 208b of the anode region 208 and the third linear cathode segment 206d of the cathode region 206 (e.g., illustrated by a third lateral distance 254) decreases in the transition area 244 in a direction away from the proximal area 242. A fourth lateral distance 256 is between the third linear anode segment 208c of the anode region 208 and the fourth linear cathode segment 206e of the cathode region 206 extending away from the transition area 244. The second lateral distance 252, third lateral distance 254, and fourth lateral distance 256 are perpendicular to the channel width and parallel to the channel length of the level-shift transistor 2002 (e.g., in x-directions).

A first lateral distance reduction is a reduction of a distance between the second linear anode segment 208b of the anode region 208 and the third linear cathode segment 206d of the cathode region 206 from proximate the level-shift transistor 2002 to distal from the level-shift transistor 2002. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor 2002. In some examples, a ratio of the first lateral dimension 248 to the first lateral distance reduction is in a range from 0 to 5.67. In some examples, a ratio of the first lateral dimension 2046 to the first lateral distance reduction is in a range from 0 to 5.67. In some examples, a ratio of the fourth lateral distance 256 to the second lateral distance 252 is in a range from 1:7 to 1:1.2.

The n-type drift layer 202 includes a first linear drift portion 202a in the transistor area 240, a conformal drift portion 202b at a transition from the transistor area 240 to the proximal area 242, a proximal drift portion 202c in the proximal area 242, a transition drift portion 202d in the transition area 244, and a second linear drift portion 202e extending laterally from the transition area 244. The first linear drift portion 202a extends linearly laterally parallel to the channel width and perpendicular to the channel length of the level-shift transistor 2002. The conformal drift portion 202b extends from the first linear drift portion 202a and conforms laterally to the periphery of the level-shift transistor 2002.

The proximal drift portion 202c extends from the conformal drift portion 202b. The proximal drift portion 202c has a first lateral edge, at which a first p-n junction 260 is formed, proximate to the first linear anode segment 208a of the anode region 208. The first lateral edge, and hence, the first p-n junction 260, extends linearly in a direction parallel to the channel width and perpendicular to the channel length of the level-shift transistor 2002. The first p-n junction 260 is formed at the first lateral edge of the n-type drift layer 202 in the epitaxial layer 306p.

The transition drift portion 202d extends from the proximal drift portion 202c. The transition drift portion 202d has a third lateral dimension 262 in a direction parallel to the channel width and perpendicular to the channel length of the level-shift transistor 2002. The transition drift portion 202d has a second lateral edge, at which a second p-n junction 264 is formed, proximate to the first linear anode segment 208a and/or second linear anode segment 208b of the anode region 208. The second lateral edge, and hence, the second p-n junction 264, extends linearly in a direction non-parallel and non-perpendicular to the channel width and the channel length of the level-shift transistor 2002. The second p-n junction 264 is formed at the second lateral edge of the n-type drift layer 202 in the epitaxial layer 306p. The second lateral edge (e.g., at the second p-n junction 264) of the transition drift portion 202d forms a second angle 266 with the first lateral edge (e.g., at the first p-n junction 260) of the proximal drift portion 202c. The second angle 266 is formed laterally interior to the n-type drift layer 202. The second angle 266 is less than 180° and may be in a range from 90° to 170°. In some examples, the first angle 250 formed by the anode region 208 is less than the second angle 266 formed by the n-type drift layer 202.

The second linear drift portion 202e extends from the transition drift portion 202d and linearly laterally parallel to the channel width and perpendicular to the channel length of the level-shift transistor 2002. The second linear drift portion 202e has a third lateral edge, at which a third p-n junction 268 is formed, proximate to the second linear anode segment 208b and/or third linear anode segment 208c of the anode region 208. The third lateral edge, and hence, the third p-n junction 268, extends linearly in a direction parallel to the channel width and perpendicular to the channel length of the level-shift transistor 2002. The third p-n junction 268 is formed at the third lateral edge of the n-type drift layer 202 in the epitaxial layer 306p.

Generally, for each of the first linear drift portion 202a, the conformal drift portion 202b, and the second linear drift portion 202e, a respective uniform distance is between the cathode region 206 and a lateral edge of the respective drift portion 202a, 202b, 202e proximate to the anode region 208, where the respective uniform lateral distance is perpendicular to an instantaneous direction of lateral extension (e.g., a tangent line) of the corresponding portion of the cathode region 206. The respective lateral distances of the drift portions 202a, 202b, 202e may be an equal lateral distance. The lateral distances for the first linear drift portion 202a and the second linear drift portion 202e are parallel to the channel length and perpendicular to the channel width of the level-shift transistor 2002 (e.g., in x-directions). The lateral distance of the conformal drift portion 202b is non-parallel and non-perpendicular to the channel length and the channel width.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the second lateral edge (e.g., at the second p-n junction 264) and the third linear cathode segment 206d of the cathode region 206 decreases (e.g., relative to the fifth lateral distance 272) in the transition area 244 in a direction away from the proximal area 242. A seventh lateral distance 276 is between the third lateral edge (e.g., at the third p-n junction 268) and the fourth linear cathode segment 206e of the cathode region 206. The fifth lateral distance 272, sixth lateral distance 274, and seventh lateral distance 276 are perpendicular to the channel width and parallel to the channel length of the level-shift transistor 2002 (e.g., in x-directions). As illustrated, the transition drift portion 202d has a lateral dimension that reduces resulting in a reduction of a lateral distance (between the second lateral edge (e.g., at the second p-n junction 264) and the cathode region 206) from the fifth lateral distance 272 in the transition area 244 proximate to the level-shift transistor 2002 to the seventh lateral distance 276 in the transition area 244 distal from the level-shift transistor 2002.

A second lateral distance reduction is a reduction of a distance between the second lateral edge (e.g., at the second p-n junction 264) and the second linear cathode segment 206c of the cathode region 206 from proximate the level-shift transistor 2002 to distal from the level-shift transistor 2002. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor 2002. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the first linear anode segment 208a of the anode region 208 and the first lateral edge (e.g., at the first p-n junction 260) of the proximal drift portion 202c of the n-type drift layer 202 in the proximal area 242. A lateral distance between the second linear anode segment 208b of the anode region 208 and the second lateral edge (e.g., at the second p-n junction 264) of the transition drift portion 202d of the n-type drift layer 202 (e.g., illustrated by a ninth lateral distance 284) may decrease in the transition area 244 in a direction away from the proximal area 242. A tenth lateral distance 286 is between the third linear anode segment 208c of the anode region 208 and the third lateral edge (e.g., at the third p-n junction 268) of the second linear drift portion 202e of the n-type drift layer 202 extending away from the transition area 244. The eighth lateral distance 282, ninth lateral distance 284, and tenth lateral distance 286 are perpendicular to the channel width and parallel to the channel length of the level-shift transistor 2002 (e.g., in x-directions).

A third lateral distance reduction may be a reduction of a distance between the first linear anode segment 208a and/or second linear anode segment 208b of the anode region 208 and the second lateral edge (e.g., at the second p-n junction 264) from proximate the level-shift transistor 2002 to distal from the level-shift transistor 2002. The third lateral distance reduction may be the difference between the eighth lateral distance 282 and the tenth lateral distance 286. The third lateral distance reduction is in a direction (e.g., in an x-direction) parallel to the channel length and perpendicular to the channel width of the level-shift transistor 2002. In some examples, a ratio of the tenth lateral distance 286 to the eighth lateral distance 282 may be in a range from 1:7 to 1:1.2. Due to the extension of the first linear anode segment 208a into the transition area 244 by the first lateral distance 246 in some examples, the lateral distance between the anode region 208 and the second lateral edge (e.g., at the second p-n junction 264) of the transition drift portion 202d of the n-type drift layer 202 may initially increase from the boundary between the proximal area 242 and the transition area 244 before decreasing in the transition area 244 in a direction away from the proximal area 242.

Although the level-shift transistor 2002 is not specifically illustrated, the level-shift transistor 2002 may include an n-type drift layer (e.g., the n-type drift layer 210, 1210). The n-type drift layer may have a lateral dimension parallel to the channel length and perpendicular to the channel width of the level-shift transistor 2002 (e.g., in an x-direction). The proximal drift portion 202c of the n-type drift layer 202 may laterally overlap in directions parallel to the channel width and perpendicular to the channel length (e.g., in y-directions) the n-type drift layer of the level-shift transistor 2002 by an overlapping lateral dimension, as described above. The n-type drift layer of the level-shift transistor 2002 may not laterally overlap in directions parallel to the channel width and perpendicular to the channel length (e.g., in y-directions) the proximal drift portion 202c of the n-type drift layer 202 by a non-overlapping lateral dimension, as described above.

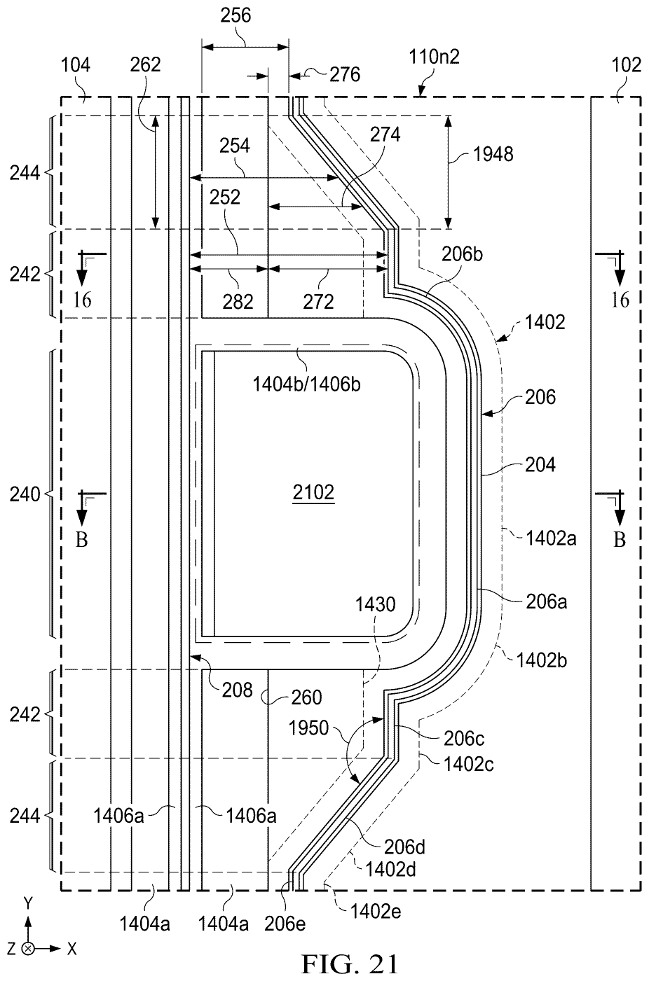

FIG. 21 is a layout of an inset 110n2 as an example of the inset 110 of FIG. 1 according to some examples. FIG. 21 shows a cross-section B-B and a cross-section 16-16. The cross-section B-B of FIG. 21 may be the cross sectional view of FIG. 15 (e.g., with an n-type LDMOS) or the cross sectional view of FIG. 18 (e.g., with a p-type LDMOS), and FIG. 16 shows a cross-sectional view of the cross-section 16-16 of FIG. 21. In FIG. 21, the level-shift transistor 2102 may be an n-type LDMOS transistor or a p-type LDMOS in an n-type epitaxial layer (or more generally, semiconductor substrate).

An n-type drift layer 1402 is disposed in the semiconductor substrate 302 (e.g., the epitaxial layer 306n and the semiconductor support substrate 304). The n-type drift layer 1402 in the illustrated example is a buried layer. A first p-type buried layer portion 1404a and a second p-type buried layer portion 1404b (collectively, p-type buried layer 1404) are disposed in the semiconductor substrate 302 (e.g., the epitaxial layer 306n). The p-type buried layer portions 1404a, 1404b form a continuous p-type buried layer 1404 that laterally encircles the level-shift transistor 2102.

An n-type well 204 is disposed in the semiconductor substrate 302 (e.g., the epitaxial layer 306n). The n-type well 204 extends from proximate the top major surface of the semiconductor substrate 302 to and contacting (e.g., extending into) the n-type drift layer 1402. A cathode region 206 is disposed in the semiconductor substrate 302 (e.g., the epitaxial layer 306n). The cathode region 206 is in the n-type well 204 and extends from the top major surface of the semiconductor substrate 302 into the semiconductor substrate 302.

A first p-type well portion 1406a and a second p-type well portion 1406b (collectively, p-type well 1406) are disposed in the semiconductor substrate 302 (e.g., the epitaxial layer 306n). The first p-type well portion 1406a and second p-type well portion 1406b each extend from proximate the top major surface of the semiconductor substrate 302 to and contacting the first p-type buried layer portion 1404a and second p-type buried layer portion 1404b, respectively. The p-type well portions 1406a, 1406b form a continuous p-type well 1406 that laterally encircles the level-shift transistor 2102. An anode region 208 is disposed in the semiconductor substrate 302 (e.g., the epitaxial layer 306n). The anode region 208 is in the first p-type well portion 1406a and extends from the top major surface of the semiconductor substrate 302 into the semiconductor substrate 302.

An n-type drift region 1430 formed by the epitaxial layer 306n is at a depth at a depth in the semiconductor substrate 302 that is generally the same depth of the n-type drift layer 1402 and the p-type buried layer 1404. The n-type drift region 1430 may correspond to portions of the proximal drift portion 202c and transition drift portion 202d of the n-type drift layer 202 described above.

The level-shift transistor 2102 (e.g., an LDMOS transistor) is laterally disposed between the cathode region 206 and the anode region 208 of the diode. The channel width of the level-shift transistor 2102 is in a direction perpendicular to a direction from the drain region 1424, 1724 to the source region 1426, 1726 (e.g., in a y-direction). A channel length of the level-shift transistor 2102 is in a direction from the drain region 1424, 1724 to the source region 1426, 1726 (e.g., in an x-direction). Hence, any direction parallel to the channel width is perpendicular to the channel length, and any direction parallel to the channel length is perpendicular to the channel width.

A proximal area 242 is near the transistor area 240 (e.g., generally neighboring the transistor area 240 in a y-direction), and a transition area 244 adjoins the proximal area 242. The proximal area 242 is between the transistor area 240 and the transition area 244. The transition area 244 is defined, for example, by a reduction in a lateral dimension of an n-type drift region formed by the epitaxial layer 306n (e.g., n-type drift region 1430) and/or in a lateral distance between the cathode region 206 and a lateral edge of the first p-type buried layer portion 1404a.

The cathode region 206 includes a first linear cathode segment 206a in the transistor area 240, a conformal cathode segment 206b at a transition from the transistor area 240 to the proximal area 242, a second linear cathode segment 206c in the proximal area 242, a third linear cathode segment 206d in the transition area 244, and a fourth linear cathode segment 206e extending laterally from the transition area 244. The first linear cathode segment 206a extends linearly laterally parallel to the channel width and perpendicular to the channel length of the level-shift transistor 2102. The conformal cathode segment 206b extends from the first linear cathode segment 206a and conforms laterally to the periphery of the level-shift transistor 2102. The second linear cathode segment 206c extends from the conformal cathode segment 206b and linearly laterally parallel to the channel width and perpendicular to the channel length of the level-shift transistor 2102.

The third linear cathode segment 206d extends from the second linear cathode segment 206c and linearly laterally non-parallel to the channel width and non-perpendicular to the channel length of the level-shift transistor 2102. In a direction perpendicular to the channel length and parallel to the channel width (e.g., in a y-direction), the third linear cathode segment 206d extends laterally a first lateral dimension 1948. An angle 1950 is formed by respective lateral sides of the second linear cathode segment 206c and the third linear cathode segment 206d proximate to the anode region 208. The angle 1950 is less than 180° and may be in a range from 90° to 170°. The fourth linear cathode segment 206e extends from the third linear cathode segment 206d and linearly laterally parallel to the channel width and perpendicular to the channel length of the level-shift transistor 2102.

The anode region 208 extends linearly laterally parallel to the channel width and perpendicular to the channel length of the level-shift transistor 2102 (e.g., in a y-direction) through the transistor area 240, the proximal area 242, and the transition area 244 and from the transition area 244.

A second lateral distance 252 is between the anode region 208 and the second linear cathode segment 206c of the cathode region 206 in the proximal area 242 and the transition area 244. A lateral distance between the anode region 208 and the third linear cathode segment 206d of the cathode region 206 (e.g., illustrated by a third lateral distance 254) decreases in the transition area 244 in a direction away from the proximal area 242. A fourth lateral distance 256 is between the anode region 208 and the fourth linear cathode segment 206e of the cathode region 206 extending away from the transition area 244. The second lateral distance 252, third lateral distance 254, and fourth lateral distance 256 are perpendicular to the channel width and parallel to the channel length of the level-shift transistor 2102 (e.g., in x-directions).

A first lateral distance reduction is a reduction of a distance between the anode region 208 and the third linear cathode segment 206d of the cathode region 206 from proximate the level-shift transistor 2102 to distal from the level-shift transistor 2102. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor 2102. In some examples, a ratio of the first lateral dimension 1948 to the first lateral distance reduction is in a range from 0 to 5.67. In some examples, a ratio of the fourth lateral distance 256 to the second lateral distance 252 is in a range from 1:7 to 1:1.2.

The n-type drift layer 1402 includes a first linear drift segment 1402a, a conformal drift segment 1402b, a second linear drift segment 1402c, a third linear drift segment 1402d, and a fourth linear drift segment 1402e, which generally correspond with the first linear cathode segment 206a, conformal cathode segment 206b, second linear cathode segment 206c, third linear cathode segment 206d, and fourth linear cathode segment 206e, respectively. The first linear drift segment 1402a is in the transistor area 240. The first linear drift segment 1402a extends linearly laterally parallel to the channel width and perpendicular to the channel length of the level-shift transistor 2102. The conformal drift segment 1402b extends from the first linear drift segment 1402a and conforms laterally to the periphery of the p-type buried layer 1404 in the transistor area 240. The second linear drift segment 1402c extends from the conformal drift segment 1402b through the proximal area 242 and into the transition area 244. The second linear drift segment 1402c extends linearly laterally parallel to the channel width and perpendicular to the channel length of the level-shift transistor 2102. The third linear drift segment 1402d extends from the second linear drift segment 1402c in the transition area 244 and from the transition area 244. The third linear drift segment 1402d extends linearly laterally non-parallel to the channel width and non-perpendicular to the channel length of the level-shift transistor 2102. The fourth linear drift segment 1402e extends from the third linear drift segment 1402d away from the transition area 244. The fourth linear drift segment 1402e extends linearly laterally parallel to the channel width and perpendicular to the channel length of the level-shift transistor 2102.

Generally, for each of the first linear drift segment 1402a, the conformal drift segment 1402b, the second linear drift segment 1402c, the third linear drift segment 1402d, and the fourth linear drift segment 1402e, a respective uniform distance is between the cathode region 206 and a lateral edge of the respective drift segment 1402a, 1402b, 1402c, 1402d, 1402e proximate to the anode region 208, where the respective uniform lateral distance is perpendicular to an instantaneous direction of lateral extension (e.g., a tangent line) of the corresponding portion of the cathode region 206. The respective lateral distances of the drift segments 1402a, 1402b, 1402c, 1402d, 1402e may be an equal lateral distance. The lateral distances for the first linear drift segment 1402a, the second linear drift segment 1402c, and the fourth linear drift segment 1402e are parallel to the channel length and perpendicular to the channel width of the level-shift transistor 2102 (e.g., in x-directions). The lateral distances of the conformal drift segment 1402b and the third linear drift segment 1402d are non-parallel and non-perpendicular to the channel length and the channel width.

The first p-type buried layer portion 1404a extends linearly laterally parallel to the channel width and perpendicular to the channel length of the level-shift transistor 2102 (e.g., in a y-direction) through the transistor area 240, the proximal area 242, and the transition area 244 and from the transition area 244. The first p-type buried layer portion 1404a has at a first lateral edge proximate to the cathode region 206 in the proximal area 242 and the transition area 244 and extending from the transition area 244. A first p-n junction 260 is formed at the first lateral edge of the first p-type buried layer portion 1404a. The first lateral edge, and hence, the first p-n junction 260, extends linearly in a direction parallel to the channel width and perpendicular to the channel length of the level-shift transistor 2102.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the first lateral edge (e.g., at the first p-n junction 260) and the third linear cathode segment 206d of the cathode region 206 decreases (e.g., relative to the fifth lateral distance 272) in the transition area 244 in a direction away from the proximal area 242. A seventh lateral distance 276 is between the first lateral edge (e.g., at the first p-n junction 260) and the fourth linear cathode segment 206e of the cathode region 206. The fifth lateral distance 272, sixth lateral distance 274, and seventh lateral distance 276 are perpendicular to the channel width and parallel to the channel length of the level-shift transistor 2102 (e.g., in x-directions). As illustrated, a distance from a lateral edge of the transition buried layer portion 1404ab to the third linear cathode segment 206d of the cathode region 206 reduces resulting in a reduction of a lateral distance from the fifth lateral distance 272 in the transition area 244 proximate to the level-shift transistor 2102 to the seventh lateral distance 276 in the transition area 244 distal from the level-shift transistor 2102.

A second lateral distance reduction is a reduction of a distance between the first lateral edge (e.g., at the first p-n junction 260) and the third linear cathode segment 206d of the cathode region 206 from proximate the level-shift transistor 2102 to distal from the level-shift transistor 2102. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor 2102. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the anode region 208 and the first lateral edge (e.g., at the first p-n junction 260) of the first p-type buried layer portion 1404a in the proximal area 242 and the transition area 244. In the illustrated example, the eighth lateral distance 282 is uniform throughout the proximal area 242 and the transition area 244. In other examples, a lateral distance between the anode region 208 and another lateral edge of the first p-type buried layer portion 1404a may decrease in the transition area 244 in a direction away from the proximal area 242. The eighth lateral distance 282 is perpendicular to the channel width and parallel to the channel length of the level-shift transistor 2102 (e.g., in x-directions).

Although the level-shift transistor 2102 is not specifically illustrated, the level-shift transistor 2102 may include a drift region or layer (e.g., the n-type drift region 1410 or p-type drift layer 1710). The n-type drift region or layer may have a lateral dimension parallel to the channel length and perpendicular to the channel width of the level-shift transistor 2102 (e.g., in an x-direction). The first p-type buried layer portion 1404a may laterally overlap in directions parallel to the channel width and perpendicular to the channel length (e.g., in y-directions) the n-type drift region or layer of the level-shift transistor 2102 by an overlapping lateral dimension, as described above. The n-type drift region or layer of the level-shift transistor 2102 may not laterally overlap in directions parallel to the channel width and perpendicular to the channel length (e.g., in y-directions) the first p-type buried layer portion 1404a by a non-overlapping lateral dimension, as described above.

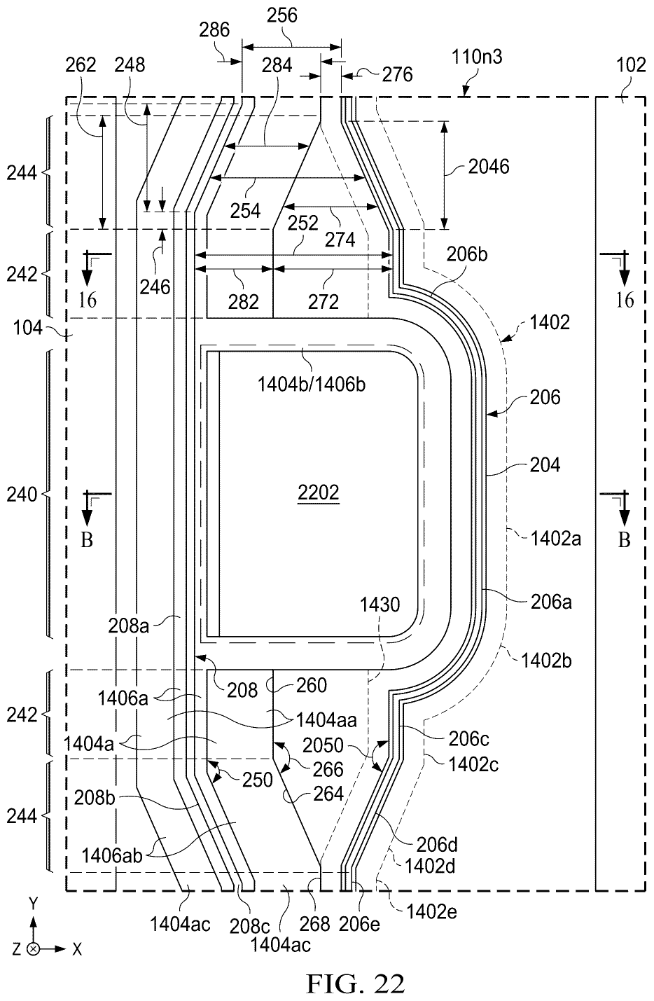

FIG. 22 is a layout of an inset 110n3 as an example of the inset 110 of FIG. 1 according to some examples. FIG. 22 shows a cross-section B-B and a cross-section 16-16. The cross-section B-B of FIG. 22 may be the cross sectional view of FIG. 15 (e.g., with an n-type LDMOS) or the cross sectional view of FIG. 18 (e.g., with a p-type LDMOS), and FIG. 16 shows a cross-sectional view of the cross-section 16-16 of FIG. 22. In FIG. 22, the level-shift transistor 2202 may be an n-type LDMOS transistor or a p-type LDMOS in an n-type epitaxial layer (or more generally, semiconductor substrate).

An n-type drift layer 1402 is disposed in the semiconductor substrate 302 (e.g., the epitaxial layer 306n and the semiconductor support substrate 304). The n-type drift layer 1402 in the illustrated example is a buried layer. A first p-type buried layer portion 1404a and a second p-type buried layer portion 1404b (collectively, p-type buried layer 1404) are disposed in the semiconductor substrate 302 (e.g., the epitaxial layer 306n). The p-type buried layer portions 1404a, 1404b form a continuous p-type buried layer 1404 that laterally encircles the level-shift transistor 2202.

An n-type well 204 is disposed in the semiconductor substrate 302 (e.g., the epitaxial layer 306n). The n-type well 204 extends from proximate the top major surface of the semiconductor substrate 302 to and contacting (e.g., extending into) the n-type drift layer 1402. A cathode region 206 is disposed in the semiconductor substrate 302 (e.g., the epitaxial layer 306n). The cathode region 206 is in the n-type well 204 and extends from the top major surface of the semiconductor substrate 302 into the semiconductor substrate 302.

A first p-type well portion 1406a and a second p-type well portion 1406b (collectively, p-type well 1406) are disposed in the semiconductor substrate 302 (e.g., the epitaxial layer 306n). The first p-type well portion 1406a and second p-type well portion 1406b each extend from proximate the top major surface of the semiconductor substrate 302 to and contacting the first p-type buried layer portion 1404a and second p-type buried layer portion 1404b, respectively. The p-type well portions 1406a, 1406b form a continuous p-type well 1406 that laterally encircles the level-shift transistor 2202. An anode region 208 is disposed in the semiconductor substrate 302 (e.g., the epitaxial layer 306n). The anode region 208 is in the first p-type well portion 1406a and extends from the top major surface of the semiconductor substrate 302 into the semiconductor substrate 302.

An n-type drift region 1430 formed by the epitaxial layer 306n is at a depth at a depth in the semiconductor substrate 302 that is generally the same depth of the n-type drift layer 1402 and the p-type buried layer 1404. The n-type drift region 1430 may correspond to portions of the proximal drift portion 202c and transition drift portion 202d of the n-type drift layer 202 described above.

The level-shift transistor 2202 (e.g., an LDMOS transistor) is laterally disposed between the cathode region 206 and the anode region 208 of the diode. The channel width of the level-shift transistor 2202 is in a direction perpendicular to a direction from the drain region 1424, 1724 to the source region 1426, 1726 (e.g., in a y-direction). A channel length of the level-shift transistor 2202 is in a direction from the drain region 1424, 1724 to the source region 1426, 1726 (e.g., in an x-direction). Hence, any direction parallel to the channel width is perpendicular to the channel length, and any direction parallel to the channel length is perpendicular to the channel width.

A proximal area 242 is near the transistor area 240 (e.g., generally neighboring the transistor area 240 in a y-direction), and a transition area 244 adjoins the proximal area 242. The proximal area 242 is between the transistor area 240 and the transition area 244. The transition area 244 is defined, for example, by a reduction in a lateral dimension of an n-type drift region formed by the epitaxial layer 306n (e.g., n-type drift region 1430) and/or in a lateral distance between the cathode region 206 and a lateral edge of the first p-type buried layer portion 1404a.

The cathode region 206 includes a first linear cathode segment 206a in the transistor area 240, a conformal cathode segment 206b at a transition from the transistor area 240 to the proximal area 242, a second linear cathode segment 206c in the proximal area 242, a third linear cathode segment 206d in the transition area 244, and a fourth linear cathode segment 206e extending laterally from the transition area 244. The first linear cathode segment 206a extends linearly laterally parallel to the channel width and perpendicular to the channel length of the level-shift transistor 2202. The conformal cathode segment 206b extends from the first linear cathode segment 206a and conforms laterally to the periphery of the level-shift transistor 2202. The second linear cathode segment 206c extends from the conformal cathode segment 206b and linearly laterally parallel to the channel width and perpendicular to the channel length of the level-shift transistor 2202.

The third linear cathode segment 206d extends from the second linear cathode segment 206c and linearly laterally non-parallel to the channel width and non-perpendicular to the channel length of the level-shift transistor 2202. In a direction perpendicular to the channel length and parallel to the channel width (e.g., in a y-direction), the third linear cathode segment 206d extends laterally a first lateral dimension 2046. An angle 2050 is formed by respective lateral sides of the second linear cathode segment 206c and the third linear cathode segment 206d proximate to the anode region 208. The angle 2050 is less than 180° and may be in a range from 90° to 170°. The fourth linear cathode segment 206e extends from the third linear cathode segment 206d and linearly laterally parallel to the channel width and perpendicular to the channel length of the level-shift transistor 2202.

The anode region 208 includes a first linear anode segment 208a in the transistor area 240 and the proximal area 242 and extending into the transition area 244, a second linear anode segment 208b in the transition area 244, and a third linear anode segment 208c extending laterally from the transition area 244. The first linear anode segment 208a extends linearly laterally parallel to the channel width and perpendicular to the channel length of the level-shift transistor 2202. The first linear anode segment 208a, as illustrated, extends into the transition area 244 by a first lateral distance 246 from the proximal area 242. Other examples may omit such a first lateral distance 246 such that the first linear anode segment 208a does not extend into the transition area 244. The second linear anode segment 208b extends from the first linear anode segment 208a and linearly laterally non-parallel and non-perpendicular to the channel width and the channel length of the level-shift transistor 2202. In a direction perpendicular to the channel length and parallel to the channel width (e.g., in a y-direction), the second linear anode segment 208b extends laterally a first lateral dimension 248. The first linear anode segment 208a of the anode region 208 forms a first angle 250 with the second linear anode segment 208b of the anode region 208. The first angle 250 is less than 180° and may be in a range from 90° to 170°. The third linear anode segment 208c extends from the second linear anode segment 208b and linearly laterally parallel to the channel width and perpendicular to the channel length of the level-shift transistor 2202.

A second lateral distance 252 is between the first linear anode segment 208a of the anode region 208 and the second linear cathode segment 206c of the cathode region 206 in the proximal area 242 and the transition area 244. A lateral distance between the second linear anode segment 208b of the anode region 208 and the third linear cathode segment 206d of the cathode region 206 (e.g., illustrated by a third lateral distance 254) decreases in the transition area 244 in a direction away from the proximal area 242. A fourth lateral distance 256 is between the third linear anode segment 208c of the anode region 208 and the fourth linear cathode segment 206e of the cathode region 206 extending away from the transition area 244. The second lateral distance 252, third lateral distance 254, and fourth lateral distance 256 are perpendicular to the channel width and parallel to the channel length of the level-shift transistor 2202 (e.g., in x-directions).

A first lateral distance reduction is a reduction of a distance between the second linear anode segment 208b of the anode region 208 and the third linear cathode segment 206d of the cathode region 206 from proximate the level-shift transistor 2202 to distal from the level-shift transistor 2202. The first lateral distance reduction is the difference between the second lateral distance 252 and the fourth lateral distance 256. The first lateral distance reduction is in a direction (e.g., in an x-direction) parallel to the channel length and perpendicular to the channel width of the level-shift transistor 2202. In some examples, a ratio of the first lateral dimension 2046 to the first lateral distance reduction is in a range from 0 to 5.67. In some examples, a ratio of the fourth lateral distance 256 to the second lateral distance 252 is in a range from 1:7 to 1:1.2.

The n-type drift layer 1402 includes a first linear drift segment 1402a, a conformal drift segment 1402b, a second linear drift segment 1402c, a third linear drift segment 1402d, and a fourth linear drift segment 1402e, which generally correspond with the first linear cathode segment 206a, conformal cathode segment 206b, second linear cathode segment 206c, third linear cathode segment 206d, and fourth linear cathode segment 206e, respectively. The first linear drift segment 1402a is in the transistor area 240. The first linear drift segment 1402a extends linearly laterally parallel to the channel width and perpendicular to the channel length of the level-shift transistor 2202. The conformal drift segment 1402b extends from the first linear drift segment 1402a and conforms laterally to the periphery of the p-type buried layer 1404 in the transistor area 240. The second linear drift segment 1402c extends from the conformal drift segment 1402b through the proximal area 242 and into the transition area 244. The second linear drift segment 1402c extends linearly laterally parallel to the channel width and perpendicular to the channel length of the level-shift transistor 2202. The third linear drift segment 1402d extends from the second linear drift segment 1402c in the transition area 244 and from the transition area 244. The third linear drift segment 1402d extends linearly laterally non-parallel to the channel width and non-perpendicular to the channel length of the level-shift transistor 2202. The fourth linear drift segment 1402e extends from the third linear drift segment 1402d away from the transition area 244. The fourth linear drift segment 1402e extends linearly laterally parallel to the channel width and perpendicular to the channel length of the level-shift transistor 2202.

Generally, for each of the first linear drift segment 1402a, the conformal drift segment 1402b, the second linear drift segment 1402c, the third linear drift segment 1402d, and the fourth linear drift segment 1402e, a respective uniform distance is between the cathode region 206 and a lateral edge of the respective drift segment 1402a, 1402b, 1402c, 1402d, 1402e proximate to the anode region 208, where the respective uniform lateral distance is perpendicular to an instantaneous direction of lateral extension (e.g., a tangent line) of the corresponding portion of the cathode region 206. The respective lateral distances of the drift segments 1402a, 1402b, 1402c, 1402d, 1402e may be an equal lateral distance. The lateral distances for the first linear drift segment 1402a, the second linear drift segment 1402c, and the fourth linear drift segment 1402e are parallel to the channel length and perpendicular to the channel width of the level-shift transistor 2202 (e.g., in x-directions). The lateral distances of the conformal drift segment 1402b and the third linear drift segment 1402d are non-parallel and non-perpendicular to the channel length and the channel width.

The first p-type buried layer portion 1404a includes a proximal buried layer portion 1404aa in the proximal area 242, a transition buried layer portion 1404ab in the transition area 244, and a linear buried layer portion 1404ac extending laterally from the transition area 244. The proximal buried layer portion 1404aa has a first lateral edge proximate to the second linear cathode segment 206c of the cathode region 206. A first p-n junction 260 is formed at the first lateral edge of the proximal buried layer portion 1404aa. The first lateral edge, and hence, the first p-n junction 260, extends linearly in a direction parallel to the channel width and perpendicular to the channel length of the level-shift transistor 2202.

The transition buried layer portion 1404ab extends from the proximal buried layer portion 1404aa. The transition buried layer portion 1404ab has a third lateral dimension 262 at a second lateral edge proximate to the third linear cathode segment 206d of the cathode region 206. The third lateral dimension 262 is in a direction parallel to the channel width and perpendicular to the channel length of the level-shift transistor 2202. A second p-n junction 264 is formed at the second lateral edge of the transition buried layer portion 1404ab. The second lateral edge, and hence, the second p-n junction 264, extends linearly in a direction non-parallel and non-perpendicular to the channel width and the channel length of the level-shift transistor 2202. The second lateral edge (e.g., at the second p-n junction 264) of the transition buried layer portion 1404ab forms a second angle 266 with the first lateral edge (e.g., at the first p-n junction 260) of the proximal buried layer portion 1404aa. The second angle 266 is formed laterally exterior to the first p-type buried layer portion 1404a. The second angle 266 is less than 180° and may be in a range from 90° to 170°. In some examples, the first angle 250 formed by the anode region 208 is less than the second angle 266 formed by the first p-type buried layer portion 1404a.

The linear buried layer portion 1404ac extends from the transition buried layer portion 1404ab and linearly laterally parallel to the channel width and perpendicular to the channel length of the level-shift transistor 2202. The linear buried layer portion 1404ac has a third lateral edge, at which a third p-n junction 268 is formed, proximate to the fourth linear cathode segment 206e of the cathode region 206. The third lateral edge, and hence, the third p-n junction 268, extends linearly in a direction parallel to the channel width and perpendicular to the channel length of the level-shift transistor 2202.

A fifth lateral distance 272 is between the first lateral edge (e.g., at the first p-n junction 260) and the second linear cathode segment 206c of the cathode region 206. A lateral distance (e.g., illustrated by a sixth lateral distance 274) between the second lateral edge (e.g., at the second p-n junction 264) and the third linear cathode segment 206d of the cathode region 206 decreases (e.g., relative to the fifth lateral distance 272) in the transition area 244 in a direction away from the proximal area 242. A seventh lateral distance 276 is between the third lateral edge (e.g., at the third p-n junction 268) and the fourth linear cathode segment 206e of the cathode region 206. The fifth lateral distance 272, sixth lateral distance 274, and seventh lateral distance 276 are perpendicular to the channel width and parallel to the channel length of the level-shift transistor 2202 (e.g., in x-directions). As illustrated, a distance from a lateral edge of the transition buried layer portion 1404ab to the third linear cathode segment 206d of the cathode region 206 reduces resulting in a reduction of a lateral distance from the fifth lateral distance 272 in the transition area 244 proximate to the level-shift transistor 2202 to the seventh lateral distance 276 in the transition area 244 distal from the level-shift transistor 2202.

A second lateral distance reduction is a reduction of a distance between the second lateral edge (e.g., at the second p-n junction 264) and the third linear cathode segment 206d of the cathode region 206 from proximate the level-shift transistor 2202 to distal from the level-shift transistor 2202. The second lateral distance reduction is the difference between the fifth lateral distance 272 and the seventh lateral distance 276. The second lateral distance reduction is in a direction (e.g., in an x-direction) parallel to the channel length and perpendicular to the channel width of the level-shift transistor 2202. In some examples, a ratio of to the third lateral dimension 262 to the second lateral distance reduction is in a range from 0 to 5.67. In some examples, a ratio of the seventh lateral distance 276 to the fifth lateral distance 272 is in a range from 1:7 to 1.2.

An eighth lateral distance 282 is between the first linear anode segment 208a of the anode region 208 and the first lateral edge (e.g., at the first p-n junction 260) of the proximal buried layer portion 1404aa in the proximal area 242. A lateral distance between the second linear anode segment 208b of the anode region 208 and the second lateral edge (e.g., at the second p-n junction 264) of the transition buried layer portion 1404ab (e.g., illustrated by a ninth lateral distance 284) may decrease in the transition area 244 in a direction away from the proximal area 242. A tenth lateral distance 286 is between the third linear anode segment 208c of the anode region 208 and the third lateral edge (e.g., at the third p-n junction 268) of the linear buried layer portion 1404ac extending away from the transition area 244. The eighth lateral distance 282, ninth lateral distance 284, and tenth lateral distance 286 are perpendicular to the channel width and parallel to the channel length of the level-shift transistor 2202 (e.g., in x-directions).

A third lateral distance reduction may be a reduction of a distance between the first linear anode segment 208a and/or second linear anode segment 208b of the anode region 208 and the second lateral edge (e.g., at the second p-n junction 264) from proximate the level-shift transistor 2202 to distal from the level-shift transistor 2202. The third lateral distance reduction may be the difference between the eighth lateral distance 282 and the tenth lateral distance 286. The third lateral distance reduction is in a direction (e.g., in an x-direction) parallel to the channel length and perpendicular to the channel width of the level-shift transistor 2202. In some examples, a ratio of the tenth lateral distance 286 to the eighth lateral distance 282 may be in a range from 1:7 to 1:1.2. Due to the extension of the first linear anode segment 208a into the transition area 244 by the first lateral distance 246 in some examples, the lateral distance between the anode region 208 and the second lateral edge (e.g., at the second p-n junction 264) of the transition drift portion 202d of the n-type drift layer 202 may initially increase from the boundary between the proximal area 242 and the transition area 244 before decreasing in the transition area 244 in a direction away from the proximal area 242.

Although the level-shift transistor 2202 is not specifically illustrated, the level-shift transistor 2202 may include a drift region or layer (e.g., the n-type drift region 1410 or p-type drift layer 1710). The n-type drift region or layer may have a lateral dimension parallel to the channel length and perpendicular to the channel width of the level-shift transistor 2202 (e.g., in an x-direction). The first p-type buried layer portion 1404a may laterally overlap in directions parallel to the channel width and perpendicular to the channel length (e.g., in y-directions) the n-type drift region or layer of the level-shift transistor 2202 by an overlapping lateral dimension, as described above. The n-type drift region or layer of the level-shift transistor 2202 may not laterally overlap in directions parallel to the channel width and perpendicular to the channel length (e.g., in y-directions) the first p-type buried layer portion 1404a by a non-overlapping lateral dimension, as described above.

An IC die including any of the respective layouts of FIGS. 12, 14, 17, 19, 20, 21, and 22, with respective cross-sectional views described therewith, may be manufactured using similar processing as described above. Appropriate implantations may be used to form doped layers, wells, and/or regions. Some implantations described previously may be separated and/or modified to accommodate the different conductivity types of various doped layers, wells, and/or regions.

Although various examples have been described in detail, it should be understood that various changes, substitutions, and alterations can be made therein without departing from the scope defined by the appended claims.

What is claimed is:

1. A semiconductor device, comprising:
a diode in a semiconductor substrate, the diode comprising:
an anode region in the semiconductor substrate;
a first n-type well in the semiconductor substrate;
a cathode region in the semiconductor substrate and in the first n-type well; and
a first n-type buried layer in the semiconductor substrate, the first n-type buried layer extending from the first n-type well laterally towards the anode region; and
a transistor comprising a source region and a drain region in the semiconductor substrate, the source region and the drain region being between the anode region and the cathode region, wherein a first lateral distance is between the cathode region and a lateral edge of the first n-type buried layer proximate the anode region, the first lateral distance being parallel to a channel length of the transistor, the first lateral distance decreasing from proximate the transistor to distal from the transistor.

2. The semiconductor device of claim 1, wherein the diode laterally encircles a first region of the semiconductor substrate, a second region of the semiconductor substrate being outside of the diode, an operating voltage rating of the first region being greater than an operating voltage rating of the second region.

3. The semiconductor device of claim 1, wherein the cathode region extends in a direction perpendicular to the channel length corresponding to where the first lateral distance decreases from proximate the transistor to distal from the transistor.

4. The semiconductor device of claim 1, wherein the anode region extends in a direction non-perpendicular to the channel length corresponding to where the first lateral distance decreases from proximate the transistor to distal from the transistor.

5. The semiconductor device of claim 4, wherein a second lateral distance between the anode region and the cathode region decreases from proximate the transistor to distal from the transistor corresponding, at least in part, to where the first lateral distance decreases from proximate the transistor to distal from the transistor, the second lateral distance being parallel to the channel length of the transistor.

6. The semiconductor device of claim 4, wherein a second lateral distance between the anode region and the first n-type buried layer decreases from proximate the transistor to distal from the transistor corresponding, at least in part, to where the first lateral distance decreases from proximate the transistor to distal from the transistor, the second lateral distance being parallel to the channel length of the transistor.

7. The semiconductor device of claim 1, wherein the transistor further includes:
a second n-type well in the semiconductor substrate, the drain region being in the second n-type well; and
a second n-type buried layer in the semiconductor substrate, the second n-type buried layer extending from the second n-type well laterally towards the source region, wherein the second n-type buried layer has a first lateral dimension parallel to the channel length, the first n-type buried layer laterally overlapping the second n-type buried layer in a direction perpendicular to the channel length by a second lateral dimension, the second lateral dimension being parallel to the channel length, the second lateral dimension being equal to or greater than 33% of the first lateral dimension.

8. The semiconductor device of claim 1, wherein the transistor is a laterally diffused metal-oxide-semiconductor (LDMOS) transistor.

9. A semiconductor device, comprising:
a diode in a semiconductor substrate, the diode comprising:
an anode region in the semiconductor substrate and at an upper surface of the semiconductor substrate; and
a cathode region in the semiconductor substrate and at the upper surface of the semiconductor substrate; and
a transistor comprising a source region and a drain region in the semiconductor substrate and at the upper surface of the semiconductor substrate, the source region and the drain region being between the anode region and the cathode region, wherein the anode region extends laterally parallel to a channel width of the transistor proximate to the transistor and extends laterally non-parallel to the channel width distally away from the transistor, a first lateral distance between the anode region and the cathode region decreasing as the anode region extends laterally non-parallel to the channel width.

10. The semiconductor device of claim 9, wherein the diode laterally encircles a first region of the semiconductor substrate, a second region of the semiconductor substrate being outside of the diode, an operating voltage rating of the first region being different than an operating voltage rating of the second region.

11. The semiconductor device of claim 9, wherein the cathode region extends in a direction parallel to the channel width corresponding to where the anode region extends laterally non-parallel to the channel width distally away from the transistor.

12. The semiconductor device of claim 9, wherein the diode further includes:
an n-type well in the semiconductor substrate, the cathode region being in the n-type well; and
a first n-type buried layer in the semiconductor substrate, the first n-type buried layer extending from the n-type well laterally towards the anode region, wherein a second lateral distance is between the cathode region and a lateral edge of the first n-type buried layer proximate the anode region, the second lateral distance being perpendicular to the channel width, the second lateral distance decreasing from proximate the transistor to distal from the transistor, wherein the anode region extends laterally non-parallel to the channel width at least partially corresponding to where the second lateral distance decreases from proximate the transistor to distal from the transistor.

13. The semiconductor device of claim 12, wherein a third lateral distance between the anode region and the first n-type buried layer decreases from proximate the transistor to distal from the transistor corresponding, at least in part, to where the second lateral distance decreases from proximate the transistor to distal from the transistor.

14. The semiconductor device of claim 12, wherein the transistor further includes a second n-type buried layer, the second n-type buried layer has a first lateral dimension perpendicular to the channel width, the first n-type buried layer laterally overlapping the second n-type buried layer in a direction parallel to the channel width by a second lateral dimension, the second lateral dimension being perpendicular to the channel width, the second lateral dimension being equal to or greater than 33% of the first lateral dimension.

15. The semiconductor device of claim 9, wherein the transistor is a laterally diffused metal-oxide-semiconductor (LDMOS) transistor.

16. A method, comprising:
forming a diode in a semiconductor substrate, the diode comprising:
an anode region in the semiconductor substrate;
a first n-type well in the semiconductor substrate;
a cathode region in the semiconductor substrate and in the first n-type well; and
a first n-type buried layer in the semiconductor substrate, the first n-type buried layer extending from the first n-type well laterally towards the anode region; and
forming a transistor comprising a source region and a drain region in the semiconductor substrate, the source region and the drain region being between the anode region and the cathode region, wherein a first lateral distance is between the cathode region and a lateral edge of the first n-type buried layer proximate the anode region, the first lateral distance being parallel to a channel length of the transistor, the first lateral distance decreasing from proximate the transistor to distal from the transistor.

17. The method of claim 16, wherein the diode laterally encircles a first region of the semiconductor substrate, a second region of the semiconductor substrate being outside of the diode, an operating voltage rating of the first region being greater than an operating voltage rating of the second region.

18. The method of claim 16, wherein the cathode region extends in a direction perpendicular to the channel length corresponding to where the first lateral distance decreases from proximate the transistor to distal from the transistor.

19. The method of claim 16, wherein the anode region extends in a direction non-perpendicular to the channel length corresponding to where the first lateral distance decreases from proximate the transistor to distal from the transistor.

20. The method of claim 19, wherein a second lateral distance between the anode region and the cathode region decreases from proximate the transistor to distal from the transistor corresponding, at least in part, to where the first lateral distance decreases from proximate the transistor to distal from the transistor, the second lateral distance being parallel to the channel length of the transistor.

21. The method of claim 19, wherein a second lateral distance between the anode region and the first n-type buried layer decreases from proximate the transistor to distal from the transistor corresponding, at least in part, to where the first lateral distance decreases from proximate the transistor to distal from the transistor, the second lateral distance being parallel to the channel length of the transistor.

22. The method of claim 16, wherein the transistor further includes:
a second n-type well in the semiconductor substrate, the drain region being in the second n-type well; and
a second n-type buried layer in the semiconductor substrate, the second n-type buried layer extending from the first n-type well laterally towards the source region, wherein the second n-type buried layer has a first lateral dimension parallel to the channel length, the first n-type buried layer laterally overlapping the second n-type buried layer in a direction perpendicular to the channel length by a second lateral dimension, the second lateral dimension being parallel to the channel length, the second lateral dimension being equal to or greater than 33% of the first lateral dimension.

23. The method of claim 16, wherein the transistor is a laterally diffused metal-oxide-semiconductor (LDMOS) transistor.
